(19) United States
(12) Patent Application Publication
(10) Pub. No.: US 2010/0224232 A1
(43) Pub. Date: Sep. 9, 2010

(54) Passively Compensative Optic and Solar Receiver

(75) Inventors: Eric Bryant Cummings, Livermore, CA (US); Leo Baldwin, Livermore, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: CoolEarth Solar, Livermore, CA (US)

(21) Appl. No.: 12/720,429

(22) Filed: Mar. 9, 2010

Related U.S. Application Data
(60) Provisional application No. 61/158,692, filed on Mar. 9, 2009.

(51) Int. Cl. H01L 31/052

(52) U.S. Cl. 136/246

(57) ABSTRACT

Embodiments of the present invention employ certain techniques, alone or in combination, to enhance a range of acceptance angles at which an apparatus may efficiently collect solar radiation. One technique positions a passive secondary optical compensator element between collected light and a receiver. In certain embodiments, the compensator element accomplishes refraction followed by at least one total internal reflection of the collected light. Another technique employs a receiver having radially-oriented strings of cells connected in series, where strings in opposing sectors are connected in parallel and in series with each other to reduce a dependence of power and/or current output, on alignment of the collector apparatus relative to a light source.

### CROSS-REFERENCES TO RELATED APPLICATIONS

This application claims the benefit of U.S. Provisional Application No. 61/158,692, filed Mar. 9, 2009, which is incorporated herein by reference in its entirety for all purposes. The application is also related to the following applications, each of which is incorporated by reference in its entirety herein for all purposes: U.S. patent application Ser. No. 11/844,888 filed Aug. 24, 2007; U.S. patent application Ser. No. 11/843,531 filed Aug. 22, 2007; U.S. patent application Ser. No. 11/844,877 filed Aug. 7, 2007; and U.S. patent application Ser. No. 11/843,549 filed Aug. 22, 2007.

### BACKGROUND OF THE INVENTION

Solar radiation is the most abundant energy source on earth. However, attempts to harness solar power on large scales have so far failed to be economically competitive with most fossil-fuel energy sources.

One reason for the lack of adoption of solar energy sources on a large scale is that fossil-fuel energy sources have the advantage of economic externalities, such as low-cost or cost-free pollution and emission. Political solutions have long been sought to right these imbalances.

Another reason for the lack of adoption of solar energy sources on a large scale is that the solar flux is not intense enough for direct conversion at one solar flux to be cost effective. Solar energy concentrator technology has sought to address this issue.

Specifically, solar radiation is one of the most easy energy forms to manipulate and concentrate. It can be refracted, diffracted, or reflected, to many thousands of times the initial flux, utilizing only modest materials.

With so many possible approaches, there have been a multitude of previous attempts to implement low cost solar energy concentrators. So far, however, solar concentrator systems cost too much to compete unsubsidized with fossil fuels.

Accordingly, there is a need in the art for improved apparatuses and methods for the collection of solar energy.

### BRIEF SUMMARY OF THE INVENTION

Embodiments in accordance with the present invention generally relate to solar radiant energy concentration. Particular embodiments of the present invention employ certain techniques, alone or in combination, to enhance a range of acceptance angles at which an apparatus may efficiently collect solar radiation. One technique positions a passive secondary optical compensator element between collected light and a receiver. In certain embodiments, the compensator element accomplishes refraction followed by at least one total internal reflection of the collected light. In certain embodiments, compensation may be accomplished with redundant cells. In certain embodiments, compensation is accomplished using reflection. Another technique employs a receiver having radially-oriented strings of cells connected in series, where strings in opposing sectors are connected in parallel and in series with each other to reduce a dependence of power and/or current output, on alignment of the collector apparatus relative to a light source.

These and other embodiments of the present invention, as well as its features and some potential advantages are described in more detail in conjunction with the text below and attached figures.

### BRIEF DESCRIPTION OF THE DRAWINGS

FIG. 1 shows an oblique view of the front surface of a monolithic secondary optic according to an embodiment of the present invention.

FIG. 2 shows an oblique view of the back surface of the monolithic secondary optic shown in FIG. 1

FIG. 3A shows a top view of the optic in FIGS. 1 and 2.

FIG. 3B shows a cross-sectional view of the optic in FIG. 3A along the cutline A-A′.

FIG. 4 shows a bottom view of the optic in FIGS. 1-3B.

FIG. 5A shows a ray trace of the radial operation of the optic in FIGS. 1-4. FIG. 5B shows a ray trace in which the primary concentrator/secondary optic pair is rotated counterclockwise from ideal. FIG. 5C shows a ray trace in which the primary concentrator/secondary optic pair is rotated clockwise from ideal.

FIG. 6 shows an embodiment including a comb-like structure comprising metal fingers joined at a metal bus bar having wire or ribbon bond pads.

FIG. 7 shows an embodiment of a receiver designed to accommodate a substantially circular lobe comprising an arrangement of die on a low-thermal-resistance circuit board or substrate.

FIG. 8 is an illustration showing a receiver having edge-only compensation in quadrants.

FIGS. 9A-9B shows a light collection system comprising an optic concentrator according to an embodiment of the present invention.

FIG. 10 shows a schematic view of a concentrator system according to an embodiment of the present invention.

FIG. 10A is a cross-sectional view of an embodiment of a receiver including a cooling system, a substrate, a Concentrated Photo Voltaic (CPV) die, an optical coupling layer, and a secondary optical compensator.

FIG. 11 is a diagram showing intensity distribution of light in the plane of the secondary optical compensator.

FIG. 12 shows partitioning of an embodiment of a secondary optical compensator into cells of equal irradiance.

FIG. 12A shows an alternative partitioning of the secondary optical compensator into hexagonal cells, in this case regular hexagons.

FIG. 12B shows a single cell from FIG. 12A with a top hexagonal refractive collection aperture and a rectangular or square total-internal-reflection (TIR) exit aperture.

FIG. 13 shows an embodiment of a receiver positioned before the focus of a primary concentrator.

FIG. 14 shows an embodiment of a receiver placed after the focus of a primary concentrator.

FIG. 15 shows an embodiment of an edge element of the secondary optical compensator in converging rays from the primary concentrator as encountered before focus.

FIG. 16 shows an embodiment of an edge element of the secondary optical compensator in diverging rays from the primary concentrator as encountered after focus.

FIG. 17 shows an embodiment of a concentrator structure experiencing a tracking error.

FIG. 18 shows a displacement of the light lobe under a tracking error.

FIG. 19 shows optical compensation of tracking errors by an extra outer ring of optical elements.

FIG. 20 shows optical compensation of tracking errors by refractive/reflective extension to the outer ring of optical elements.

FIG. 20A shows an optical compensation method as in 20 but adapted to a linear array of energy conversion cells as would be deployed with a trough primary concentrator.

FIG. 20B shows an optical compensation method as in 20A but adapted to linear array comprising 2 or more rows of energy conversion cells (an embodiment for 2 rows is shown).

FIG. 21 shows optical compensation of tracking errors by a reflective collar around the outer-most ring of optical elements for the divergent ray case, in communication with the cooling system used for the substrate of the receiver.

FIG. 22 shows optical compensation at a center of the receiver by a reflective protrusion from the center of the receiver. FIG. 22A shows an enlarged view of FIG. 22.

FIG. 23A shows an alternative embodiment of optical compensation by a reflective protrusion from the center of the receiver, the reflective protrusion having flat planes.

FIG. 23B shows an alternative embodiment of optical compensation by a reflective protrusion from the center of the receiver, the reflective protrusion having concave planes.

FIG. 23C shows an alternative embodiment of optical compensation utilizing a reflective protrusion from a center of the receiver

FIG. 24A shows optical compensation at the center of the receiver by a refractive element placed in front of the secondary optic.

FIG. 24B shows optical compensation at the center of the receiver by a refractive and totally internal reflective element placed in front of the secondary optic.

FIG. 25 shows an alternative embodiment of a secondary optical compensator suited for lower concentration ratios, comprising a first planar refracting surface and a second refracting surface having lenslets.

FIG. 26 shows an alternative embodiment of a secondary optical compensator suited for intermediate concentration ratios, comprising two refracting surfaces that both include lenslets.

FIG. 27 shows a secondary optical compensator comprising a flat glass element having optical features on one or both sides, that is co-molded or otherwise attached and formed from a suitable molded polymer such as silicone.

FIG. 28 shows a flow chart of a process for optimizing design of a secondary optical compensator using numerical methods, including multi-variable optimization, fractional weighting, and downhill simplex methods.

FIG. 29 shows reflection of incident light to a receiver according to an embodiment of the present invention.

FIG. 30 shows a simplified schematic drawing of an embodiment of a computer system in accordance with the present invention, comprising a processor that is configured to produce certain outputs based upon one or more inputs.

FIG. 31 shows a simplified view of a computer system suitable for use in connection with the methods and systems of the embodiments of the present invention.

FIG. 31A is an illustration of basic subsystems in the computer system of FIG. 31.

FIG. 32A is an illustration of an irradiance profile on a surface produced by a primary collector or system of optics.

FIG. 32B is an illustration of an illumination pattern corresponding to a mispointed or otherwise off-design condition.

FIG. 32C is an illustration showing three candidate locations for compensating cells.

FIG. 32D is an illustration showing possible compensating arrangements used to improve power compensation.

FIG. 32E is another illustration showing the placement of elements used to improve power compensation.

FIGS. 33A-33B illustrated two ways of redistributing energy in an apparatus.

FIGS. 34-35 illustrate examples of optical compensation systems used to redistributing energy.

FIGS. 36-37 show optical interactions including beam splitting caused by an optical compensation system.

FIGS. 38A-38B are illustrations showing optical interactions caused by primitive splitters.

FIGS. 39A-39C are illustrations showing optical interactions caused by combiners.

### DETAILED DESCRIPTION OF THE INVENTION

As used herein, the term “primary concentrator” refers to elements of an optical system that direct light to a “secondary optical system.” Embodiments of concentrators which may be used in accordance with embodiments of the present invention include but are not limited to those described in U.S. patent application Ser. No. 11/843,531, which is incorporated by reference in its entirety herein for all purposes. In some embodiments of the present invention, this secondary optical system comprises a “passive optical compensator” and an energy-converting receiver. Embodiments of receivers which may be used in accordance with embodiments of the present invention include but are not limited to those described in U.S. patent application Ser. No. 11/844,888, which is incorporated by reference in its entirety herein for all purposes. In some embodiments of the present invention, this receiver is a “passive electrical compensator.”

The primary concentrator may comprise at least one reflective, refractive, or diffractive surface or volume, in various combinations, to form at least one concentrated illumination pattern, herein called a “lobe.” The “secondary optical system” refers to all elements in optical communication with the primary concentrator leading to and including conversion of optical energy and any combining of this energy prior to transmission of the converted energy from the vicinity of the energy converters.

In some embodiments, these energy converters comprise optical to thermal energy converters (absorbers). In some embodiments, these converters include optical-to-electric converters such as photovoltaic cells, (e.g., monocrystalline, polycrystalline, amorphous, bulk, thick film, thin film, single junction, multiple-junction, etc.), or optical absorbers, followed by thermal energy-to-electricity converters. In certain embodiments of the present invention, these converters comprise optical to chemical energy (photolytic) converters or optical to thermal to chemical (thermolytic or pyrolytic) converters.

The “acceptance angle” of a concentrated photovoltaic system is the angular range of illumination over which near-maximal electrical power is produced. A large acceptance angle is favorable because it relaxes pointing accuracy and structural stability requirements.

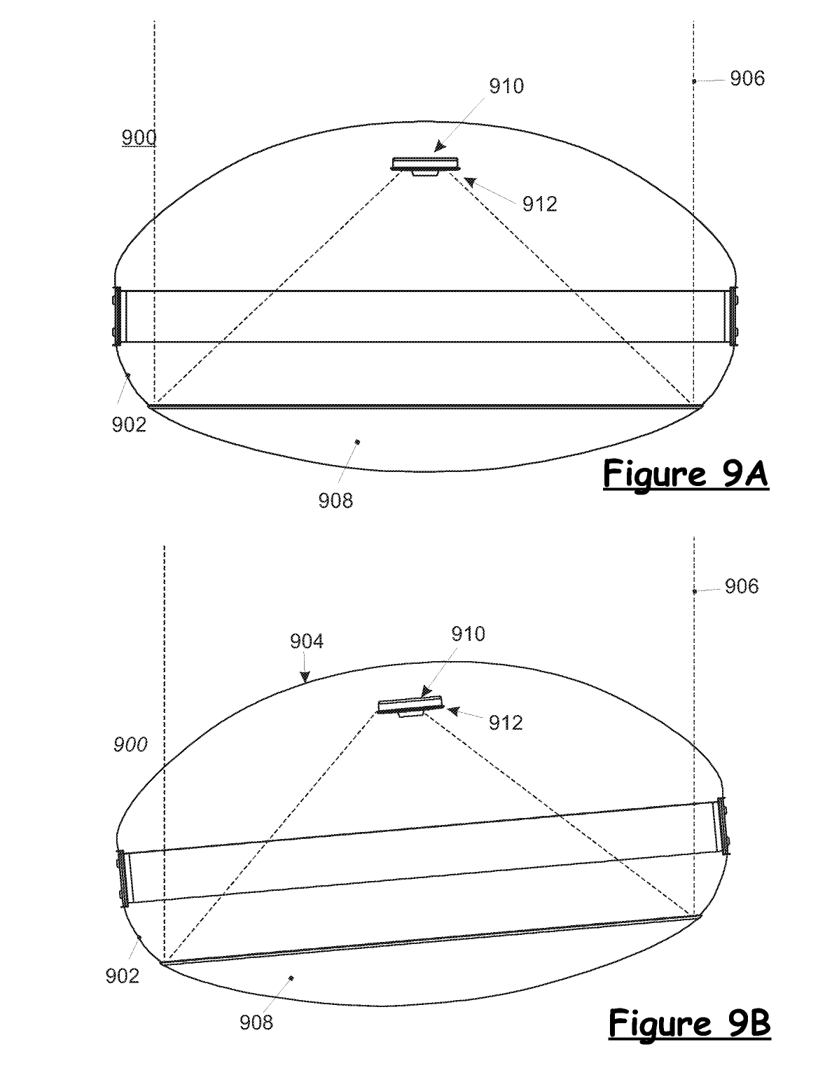

FIGS. 9A-B show a simplified schematic view of an embodiment of a solar collection apparatus employing a passive secondary optical element configured to enhance the “acceptance angle”. Specifically, collection apparatus 900 comprises an inflated balloon 902 having an upper surface 904 transparent to incident light 906, and a primary concentrating element in the form of a lower surface 908 that is configured to reflect the incident light to a receiver 910.

As shown in FIG. 9A, under certain circumstances the primary concentrating element may be precisely aligned with the incident light, maximizing the amount of collected solar radiation. As shown in FIG. 9B, however, under other circumstances the primary concentrating element may not be exactly aligned with the incident light, such that the reflected light is offset.

Accordingly, the system 900 of FIGS. 9A-B includes a secondary passive solar compensator element 912 that is configured capture this offset reflected solar radiation, thereby maximizing the amount of light that is collected. As further discussed below, novel electrical interconnection techniques may be employed alone or in combination with the optical compensation to substantially expand the acceptance angle of the system. Through use of optical compensation or electrical interconnection techniques employed alone or in combination, embodiments of the present invention may allow acceptance angles including but not limited to the range of between about 0.1 to 10 degrees, with some embodiments having a range of acceptance angles between about 0.25 to 2 degrees.

In a single channel arrangement, one primary optic feeds light to one secondary optic and thence to one solar cell. While a number of effective techniques have been developed to increase the acceptance angle of a concentrator feeding a single solar cell in a single channel arrangement, no general approach has yet solved the problem of optimizing acceptance angle of a dense array of series-connected solar cells. This problem is considerably more complicated because the maximum power point of a solar cell occurs at a current that is substantially proportional to its total irradiance.

In addition, the relationship between acceptance angle and concentration ratio is fundamentally limited by the relationship C≦(n/θ)², where C is the concentration ratio, n is the index of the media, and θ is the acceptance angle. Whereas any one cell of a monolithic receiver obeys this relationship, a system comprising a plurality of such cells in the receiver may be capable of extending the acceptance angle beyond this limit.

A series string of cells can operate at maximum efficiency if individual cells have the same maximum-efficiency current, requiring a careful balance of irradiance per cell. Increasing the acceptance angle of a series-connected array requires an optic system that maintains this careful balance over an extended illumination-angle range.

An optical system that controls fluxes in this manner is called an “optical compensator.” Compensation accomplished purely optically (e.g., via refraction, diffraction, and/or reflection), is called “passive optical compensation”. Accordingly, as used herein, an optical system is called a “passive optical compensator.”

Alternatively, maximum efficiency may be maintained by arranging cells in a network of series and parallel connections, such that all cells maintain their maximum-efficiency current in spite of shifting illumination. Such an arrangement of cells is denoted as “electrical compensation”, and more specifically as “passive electrical compensation” if the interconnections are static (e.g., via fixed printed circuit board trace patterns rather than electronic switches.) As used herein, a system that performs such compensation is called a “passive electrical compensator.”

Individually, passive optical or electrical compensation can produce at best a limited acceptance angle. However, a combination of optical and electrical compensation can be used to expand the acceptance angle considerably over individually applied solutions.

Secondary Optical Passive Compensator and Concentrator

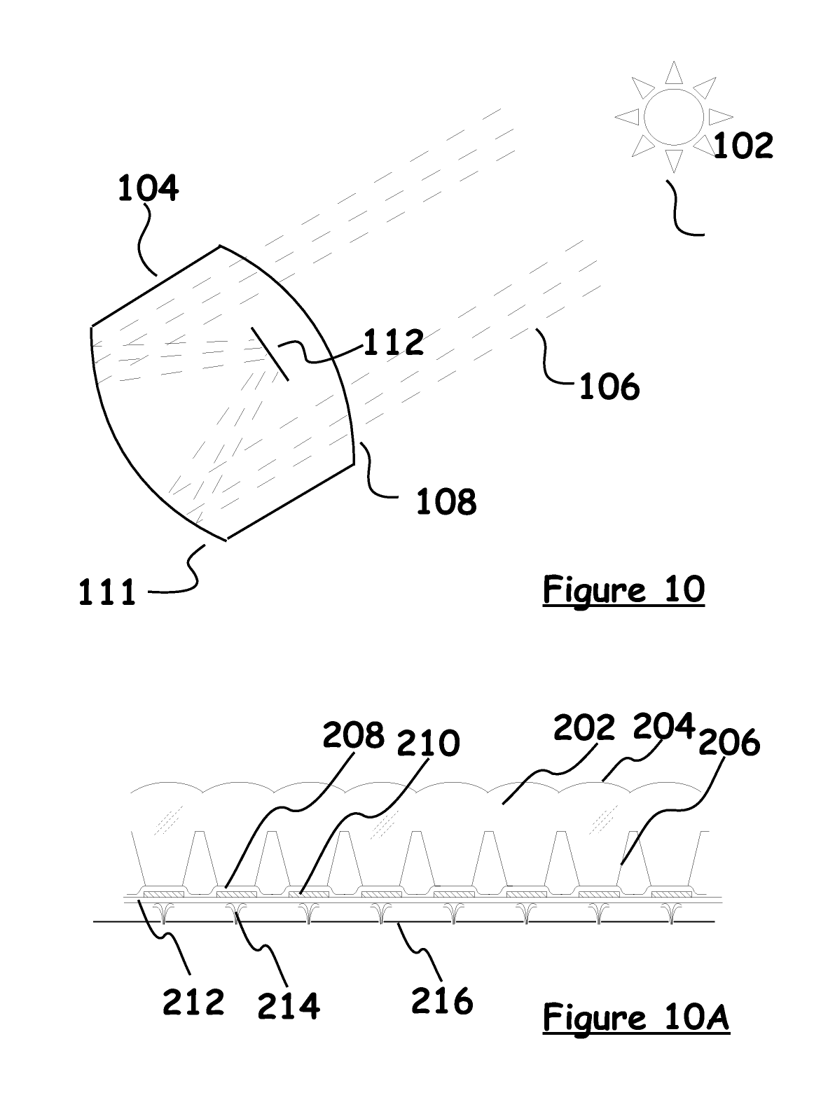

FIG. 10 shows a schematic view of a concentrator system according to an embodiment of the present invention.

FIG. 10A is a cross-sectional view of an embodiment of a receiver including a cooling system 214, a substrate 212, energy conversion cells 210, an optical coupling layer 208, and a secondary optical compensator 202. Rays (not shown) enter the first positive refractive surface 204 of secondary optical compensator 202 and are directed to second surface 206 which is a light pipe that further concentrates the light and makes it more uniform by Total Internal Reflection (TIR). If secondary optic 202 is, for example, made from glass it will not be in direct contact with energy conversion cells 210 but the two surfaces will be optical contact through optical coupling layer 208 which can conform to the two proximate surfaces of 206 and 210. Energy incident on conversion cells 210 that is not converted, for example to electrical power, passes into substrate 212 and is removed by a cooling system shown here as water or another suitable cooling liquid directed at the second surface of substrate 212 as jets 214 through aperture plate 216.

A solar concentrator may produce a spatially non-uniform illumination. Efficient concentrators produce illumination patterns that fall sharply off at the periphery of at least one concentrated lobe. In particular, the primary concentrator structure described herein may produce a lobe that is in general spatially non-uniform.

The energy within a lobe is also generally not uniformly distributed. Often the central portion of a lobe has a marked deficit or surplus of illumination.

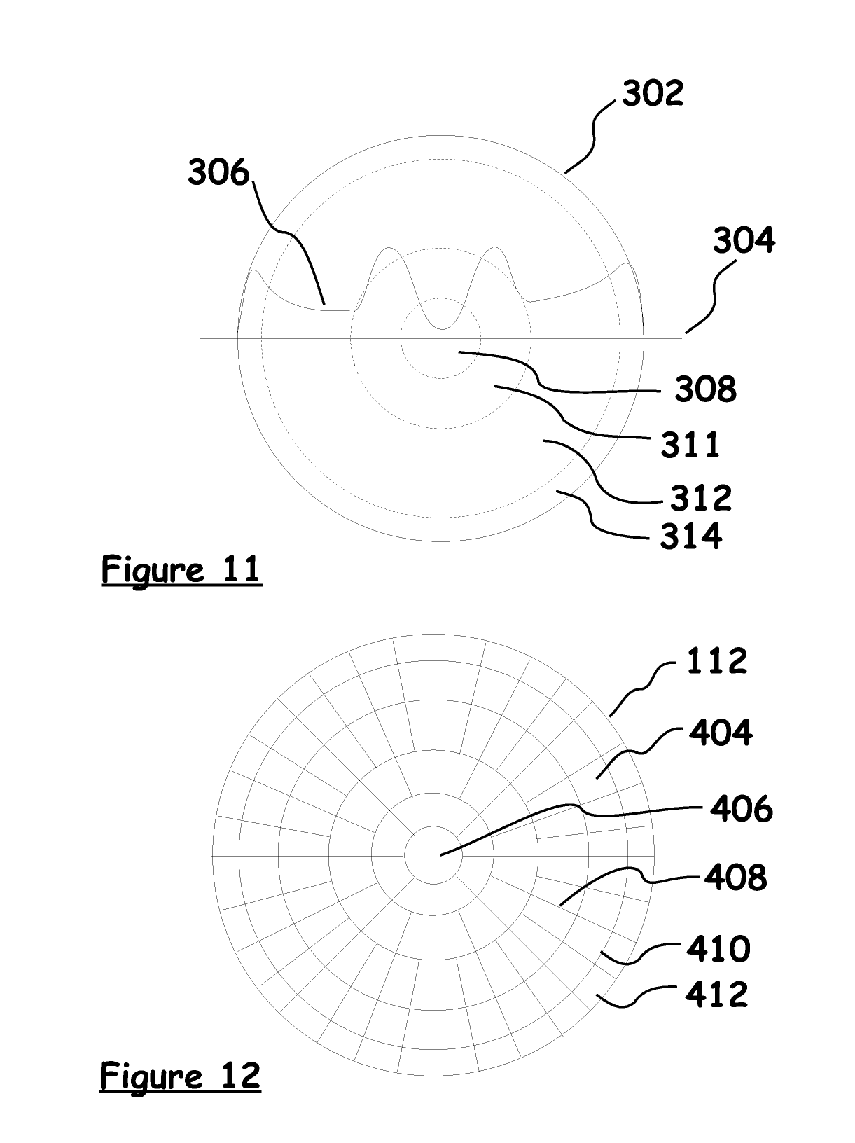

FIG. 11 shows a simplified view of a representative lobe 302 that may be produced by an embodiment of a primary concentrator structure. While this lobe is substantially rotationally symmetric, a non-uniform intensity profile 306 is shown across any particular diameter 304. Such an intensity distribution can be grouped into zones, in this example a dark central zone 308 surrounded by a bright annular zone 311, in turn surrounded by an intermediate zone 312 surrounded by an outer bright annular zone 314.

When designing a monolithic receiver, a first step may be to partition the area of the receiver into areas of equal irradiance. Such partitioning allows the use of a plurality of the same or similar energy conversion cells, which may confer economies of scale in purchasing components for the device.

According to some embodiments, an alternative first step may be to partition the area of the receiver into areas of particular irradiance. An example of such an approach would be to partition the receiver into areas of equal maximum irradiance under anticipated operational conditions. Such operational conditions could take into account other than the most favored lobe shapes, and may result in partitioning a receiver into areas that do not have equal irradiance in a nominal operational condition.

In certain embodiments, the receiver may be partitioned into areas of relative irradiance that are related by specific ratios. In some embodiments said ratios may be determined, for example, to facilitate passive electrical compensation. In some embodiments, ratios are integral, e.g., 1:1, 2:1, 3:1, etc. or 2:3, 3:4, etc. Ratios can be ratios of integer numbers, non-integer numbers, real numbers or combinations of these. In some embodiments, ratios change for off-design conditions, e.g., mispointing.

According to certain embodiments, under nominal operating conditions the partitioning divides the incident energy substantially equally among the plurality of energy conversion cells, for example silicon photovoltaic cells. In alternate embodiments, a specific manner of partitioning of the cells may represent a trade-off between operating conditions within a defined envelope, such as a defined budget for tracking error.

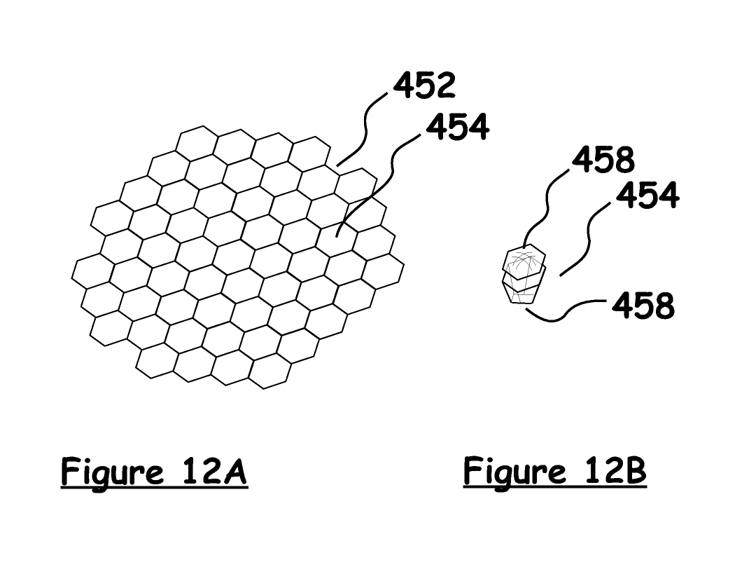

An example of a partitioned monolithic receiver is shown in FIG. 12. In this embodiment, a ring and ray structure has been selected, with reference number 408 showing an example of a ray and reference number 410 showing a ring.

While the embodiment of FIG. 12 shows a receiver structure having an arrangement of cells in rings, this arrangement is not required by the present invention and alternatives are possible. For example, other tessellating structures can also be selected, such as square or rectangular, or hexagonal. An example of an alternate arrangement of cells is shown in FIG. 12A with hexagonal cells. A single cell 454 from array 452 is shown in FIG. 12B. In this embodiment, the first surface of the cell 458 is refractive and a positive lens to concentrate light incident on it from the primary concentrator. The second surface of the cell 458 is a TIR light pipe, hexagonal proximate to the first surface for best energy transfer from the first surface and square or rectangular at the other end where it is proximate to an energy conversion cell of similar dimensions.

In FIG. 12, receiver 112 is partitioned into a number of cells 404. The number of cells may be selected to fulfill multiple performance criteria such as overall concentration factor, an ability to subdivide the receiver into sufficient cells that each cell can adequately approximate the equal energy condition, and a sufficiently small number of cells to contain manufacturing costs.

An annular receiver structure with a central hole in this embodiment, corresponds well with the central low irradiance zone 308 in the irradiance plot 306 of the lobe 302 shown in FIG. 11. Similarly, the outer ring of cells of receiver 112, for example cell 412, is smaller than cells located radially inward to account for the relatively high intensity of zone 314. In one embodiment, the cells of receiver 112 are arranged to make the light distribution shown in the irradiance plot 306 of lobe 302 more flat, which indicates a more uniform distribution of light.

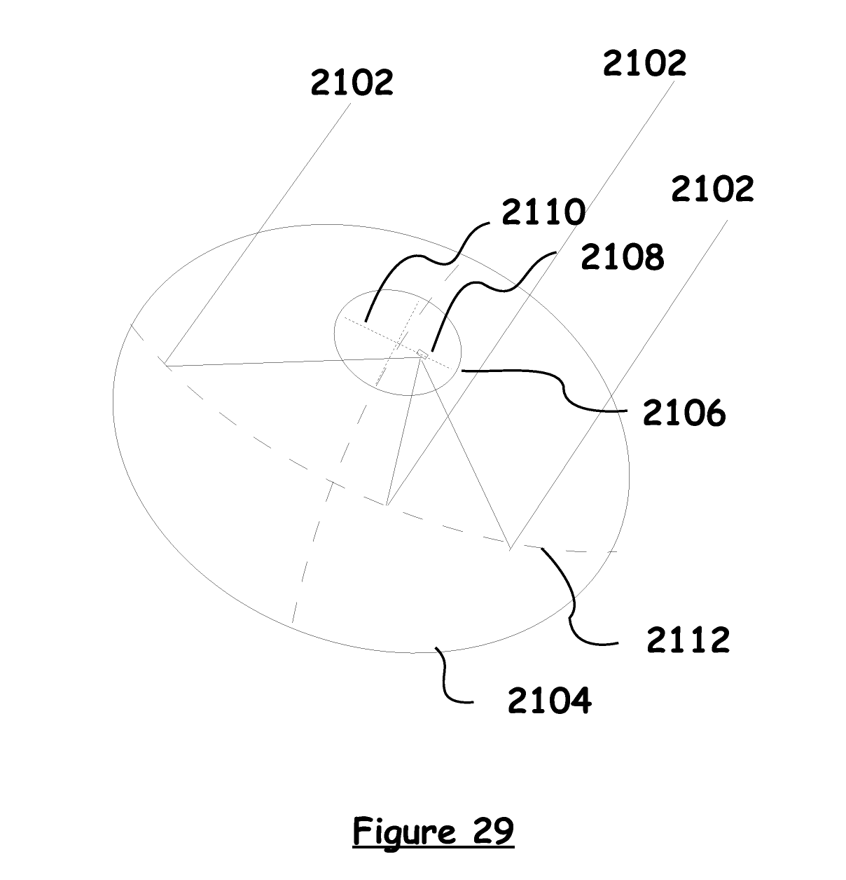

FIG. 29 demonstrates rays 2102 from the sun striking primary reflector 2104 and reflected toward receiver 2106. A cell 2108 disposed at a particular diameter of the receiver 2110 may be generally receive light from one, two, three or more regions of the primary 2104 that lay along a corresponding diameter 2112, as a result of optical aberrations and operating away from a focus.

The angular subtense of the rays 2102 as input to a particular cell 2108 is larger along the diameter 2112 of primary concentrator 2104 than across said diameter. For this reason, there may be a benefit in optical efficiency to having an aspect ratio of the cell 2108 that is related to the difference in the angular subtense of the rays along and across the diameters. Cell 2108 will in general consist of a first refractive surface 204 and a second TIR light pipe 206 and an energy conversion cell 210 as shown in FIG. 10A and described herein.

In certain embodiments, the energy conversion cells are rectangular with an aspect ratio of the length and width of the optically active area of between about 1.5:1 and 10:1. In a particular embodiment the aspect ratio of the cell is 5:1, and certain embodiments may include cells having aspect ratios including but not limited to 2:1, 3:1, 4:1, 6:1, 7:1, 8:1, or 9:1.

The aspect ratio may be determined by the focal ratio of the primary optic as can be seen in FIG. 29. In FIG. 29 the primary optic 2104 is a mirror of focal ratio approximately f:0.5. Rays from the sun 2102 strike primary optic 2104 and are reflected onto receiver 2106.

A particular energy conversion cell 2108 on diametric axis 2110 is typically in optical communication with approximately three zones lying along a corresponding diametric axis 2112. While the energy from each of these zones subtends a large angle along diametric axis 2110, all zones taken together subtend a relatively small angle across said diametric axis. This disparity in the angular subtense of the optical communication between the cell 2108 and the primary optic 2104 confers an optical design advantage on a cell that has a corresponding disparity in aspect ratio. Maximum collection efficiencies, maximum packing efficiencies, and greatest uniformity of energy distribution within a cell can be satisfied by selecting a cell of optimal aspect ratio for a given primary optic.

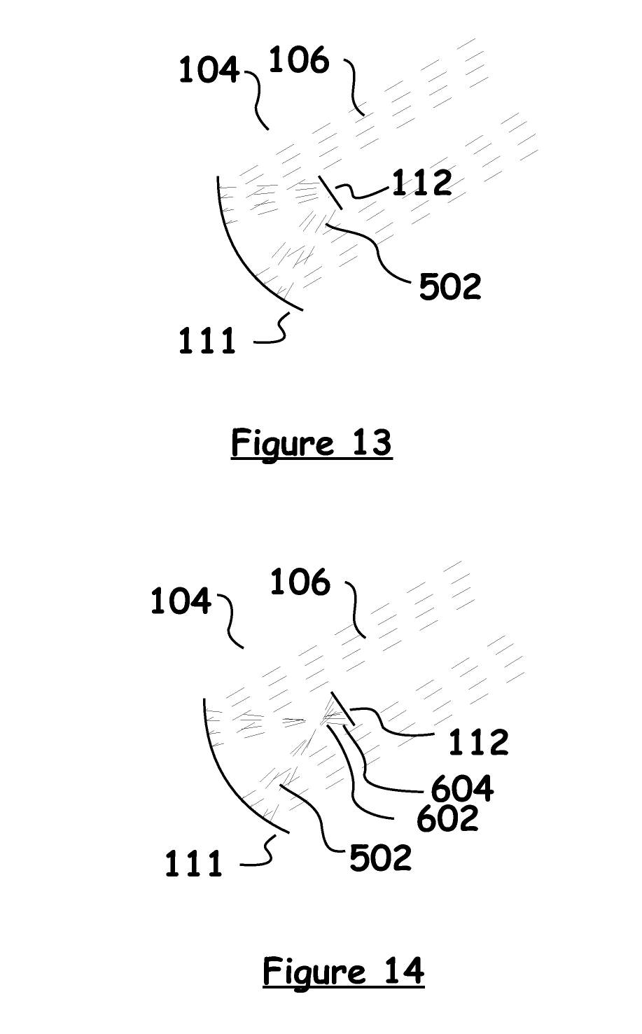

In defining a plane for the receiver, the characteristics of the primary concentrator may be considered and the position of the receiver along the optical axis determined. In the specific embodiment of FIG. 13, solar rays 106 are reflected from primary reflective optical concentrator 111 of system 104 and converge toward a focal point. Receiver 112 intercepts the convergent rays 502 before focus. The point at which receiver 112 intercepts convergent rays 508 is a design consideration for fulfilling performance requirements such as overall system concentrations, tolerance to tracking errors, and overall system dimensions.

In an alternate embodiment shown in FIG. 14, solar rays 106 are reflected from primary reflective optical concentrator 111 of system 104 and converge toward a focal point. Receiver 112 intercepts the divergent rays 604 after focus 602. Again, the point at which receiver 112 intercepts divergent rays 604 is a design consideration for fulfilling performance requirements such as overall system concentrations, tolerance to tracking errors, and overall system dimensions.

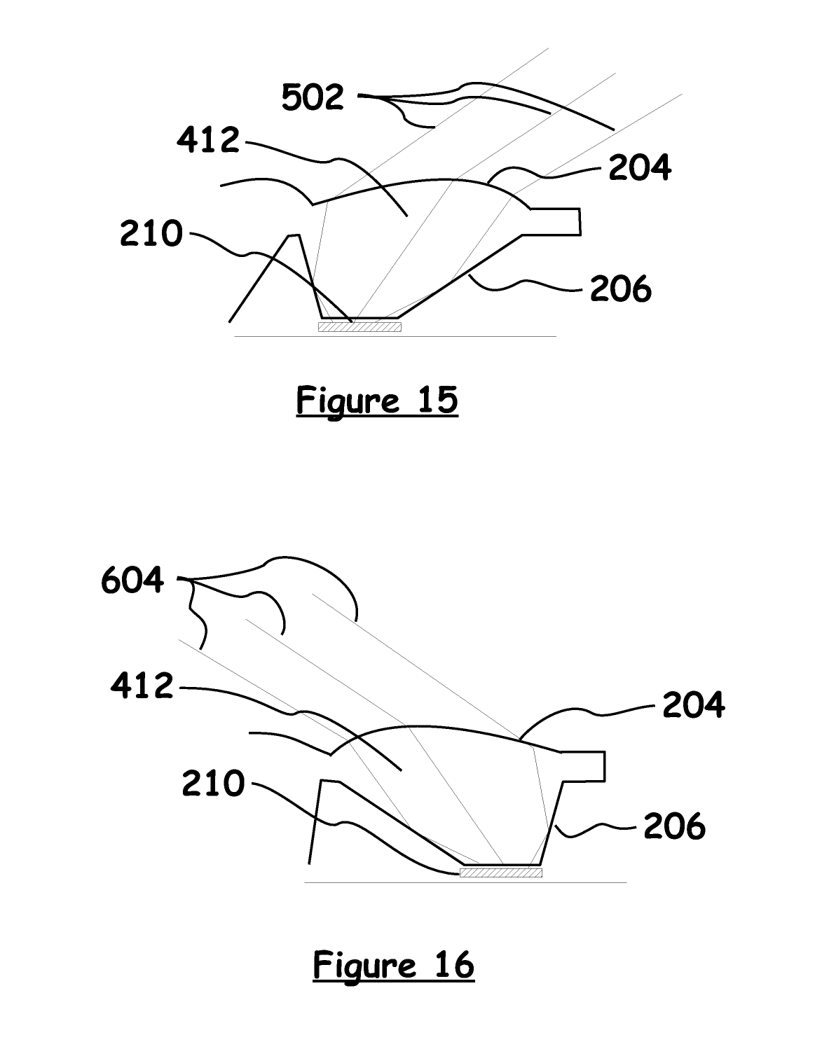

A decision to place the receiver before or after focus, may affect the optical design of the receiver. For example, in the embodiment of FIG. 15, convergent rays 502 enter the optical part of perimeter cell 412 and are refracted and reflected onto solar cell 210 with refractive surfaces 204 and TIR reflective surfaces 206 suitably designed to collect convergent rays. In the embodiment of FIG. 16, divergent rays 604 enter the optical part of perimeter cell 412 and are refracted and reflected onto solar cell 210 with refractive surfaces 204 and TIR reflective surfaces 206 suitably designed to collect convergent rays.

The illumination profile generally shifts angularly or spatially when the angle between the sun and the concentrator changes. The highest spatial gradients in illumination typically occur at the outer and central regions of a lobe, thus these regions may require tilt compensation.

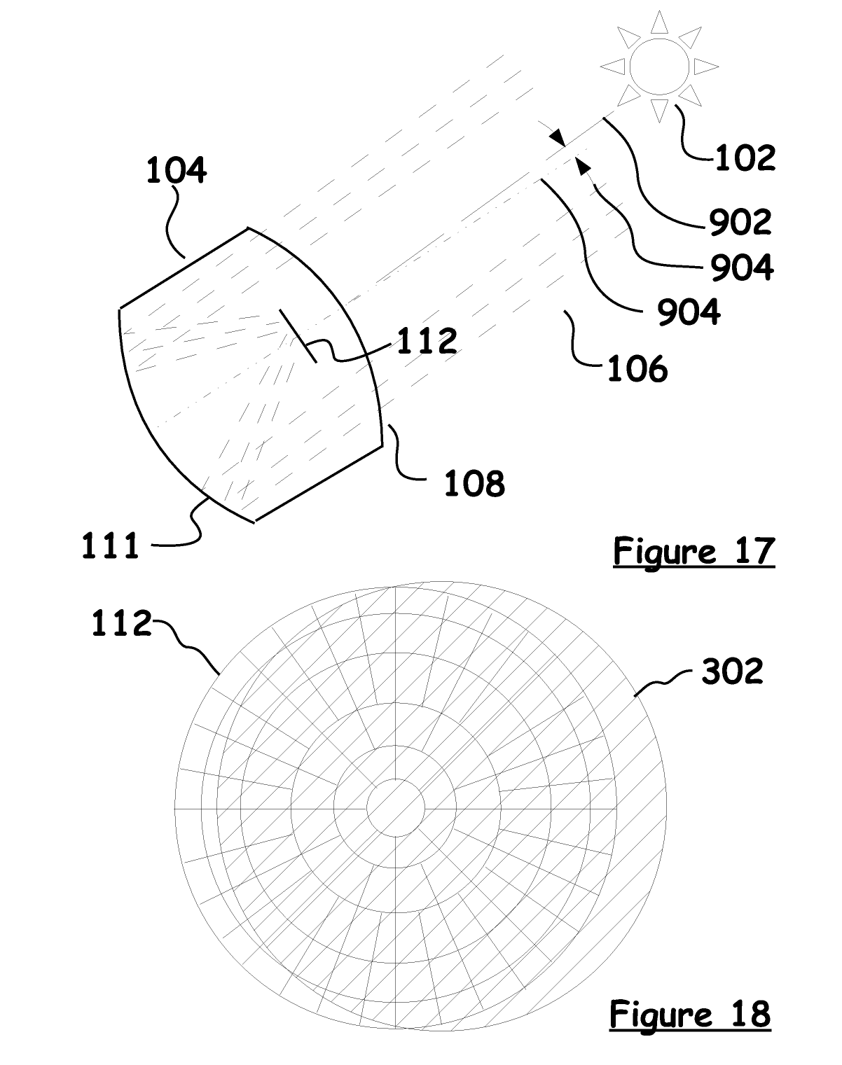

In the embodiment of FIG. 17, rays 106 from the sun 102 along solar axis 902 enter light collection system 104 offset from the system optical axis 904 with angular pointing error 904. Rays 106 are collected by optical system 104, are concentrated by primary optic 111 and are convergent on receiver 112 with a spatial offset proportional to said pointing error. This spatial offset is shown in FIG. 18, where lobe 302 is offset from receiver 112 due to pointing error 904.

In addition to these shifts, off axis behavior can produce higher-order changes in the illumination profile (e.g., caustics, etc.) These changes may also require compensation.

In some cases, primary concentrators may be engineered to provide favorable lobes. One favorable lobe would be uniformly illuminated with sharp edges. Such a lobe only requires compensation at the periphery against angular or spatial shifts.

Another example of a favorable lobe is substantially uniform except for a small region toward the center, which requires further, localized, compensation. Less favorable, lobes may, in addition have low-spatial-frequency variations across them. This situation describes the lobe that may be produced by a battened, circular, inflated reflective film.

An example of a passive secondary optic according to an embodiment of the present invention can employ a number of refractive, reflective, and/or diffractive elements to redirect and distribute light. The passive secondary optic may provide additional concentration or reduce the concentration to achieve compensation.

Classes of solutions involving metallic reflectors may be problematic since reflections tend to compound pointing errors. Moreover, at high concentration factors these mirrors may require active cooling, e.g., forced air or water cooling.

Classes of solutions that employ a number of elements may suffer from surface reflections (Fresnel losses) and scattering. Some designs can mitigate losses from surface reflections by capturing reflected light. Others may reduce such losses by anti-reflection coating.

Because solar cells are fragile and sensitive to the elements, a photovoltaic receiver generally requires an encapsulant or protective layer. Examples of such an encapsulant or protective layer include but are not limited to silicone oil, an elastomer or a gel, or a combination thereof. At high concentration factor, that protective layer may be made of glass to avoid premature damage by concentrated ultraviolet light exposure. Such a rigid or semi-rigid layer such as a silicone elastomer layer provides at least one refractive surface that could be used for optical compensation and further concentration.

A simple class of secondary optic comprises structuring the front surface of the protective layer with a refractive or diffractive pattern to shape the incoming rays. In such structures, the back surface of the protective layer can also be used to guide beams.

In some embodiments, the back surface is structured to form total-internal-reflection (TIR) concentrating light pipes. In some embodiments, the back surface is structured to form a TIR mirror to direct light radially to compensate for mispointing.

Some embodiments may further use a front surface TIR mirror in conjunction with a back surface TIR mirror to direct light. In some embodiments, front surfaces double as refractor for incoming rays and mirror for internal rays.

Very “fast” or aberrated rays from a primary concentrator typically require an optic having a significant depth to avoid needing an excessively large-diameter receiver. However, thick optics can be expensive and heavy to produce and support. Moreover, optics that combine thick and thin regions may be difficult to cast or stamp.

Thus, to avoid excessive casting costs and material, some secondary optics according to embodiments of the present invention may employ a second refractive element, combination refractive and TIR element, or a second reflective element. This element can provide degrees of freedom to design a structure that is more manufacturable, less expensive, and/or offers better compensation.

In certain embodiments, thick optical regions could be made hollow and filled with a refractive liquid or gel, such as water, silicone oil, paraffin, and the like. This refractive material may provide a secondary benefit, such as assisting with cooling. Beam steering from thermal gradients in the refractive material may provide a passive, but dynamic, method of optical compensation.

Examples of materials that may be suitable for use as secondary optics include but are not limited to soda lime glass, BK7, low-temperature casting glasses (such as B270), and high-index glasses. Adding an inexpensive ultraviolet (UV)-absorber to glass may be favorable for protecting polymers that may encounter concentrated light subsequently.

Polymers such as acrylic, polycarbonate, amorphous polyolefins, fluorinated compounds, silicones, epoxies, and the like may also be employed. However, care may be needed to ensure these polymers are not exposed to excessive temperatures or damaging wavelengths of light, particularly at high concentration factors. These materials may also be formulated with ultraviolet light absorbers, Hindered Amine Light Stabilizer (HALS) additives or coatings, and other techniques known in the art, to extend their lifetime under illumination. One option is to have the front surfaces of the secondary optic made of an ultraviolet and possibly blue absorbing glass, allowing the use of polymers, liquids, or gels in later optical stages that would otherwise not have an adequate service life.

Another method of protecting subsequent polymer layers from potentially damaging radiation (such as UV radiation), comprises putting a UV reflective coating on the front surface of the secondary optic. This coating may be combined with an antireflection coating for that spectrum of rays the energy conversion cells are responsive to. These techniques may be used alone or in various combinations, to provide the desired level of UV protection for optimum lifetime of UV-damage susceptible components at minimum economic cost.

Examples of suitable fabrication techniques may include casting, stamping, and injection molding. The use of TIR may impose requirements on surface smoothness. In most cases, it may be expensive to mechanically polish all TIR surfaces after forming the optic.

Accordingly, several techniques may be used to avoid the need for post polishing. For example, techniques such as flame and acid polishing and others known in the art may be employed to reduce high-spatial-frequency surface waviness. Another possible technique is the use of highly polished and maintained molds. Still another approach may employ designs having relatively large draft angles.

Yet another technique may be to avoid approaching TIR critical angle limits. Such TIR critical angle limits in a nominal design may provide a tolerance for angular errors introduced by manufacturing artifacts such as surface waviness and other errors

Another approach to obtaining a high-quality casting, is to produce a composite glass and polymer optic. The polymer could be injection molded into a glass stamping or casting. Polymer injection molding economically provides superior surfaces because of the significantly longer mold life and process control.

Such features may be incorporated on one or both sides. In certain embodiments the glass may be flat plain glass with polymeric features. In some embodiments the glass may have molded or pressed features on one side (for example refractive features), and be flat on the other side with polymeric features formed directly on the glass, such as by direct polymerization of silicone polymer onto glass. Examples of such structures are TIR light pipes.

In the case where the light pipes are produced from silicone or other suitable polymers, it may be possible for the polymer light pipes to be in direct optical contact with the energy conversion cells. A resilient coupling layer may no longer be needed to interface the secondary optic to the conversion cells if the secondary optic is itself sufficiently resilient.

Alternatively, a self-leveling polymer layer could be applied, e.g., by spray, dipping, centrifuge, etc. to a glass optic to improve TIR. Alternatively, a polymer optic may be injection molded separately from the glass piece and used with an air gap, index-matching liquid or gel, or optically clear adhesive between it and the glass piece. Alternatively, the plastic piece may be thermally, ultrasonically or otherwise sealed to the glass.

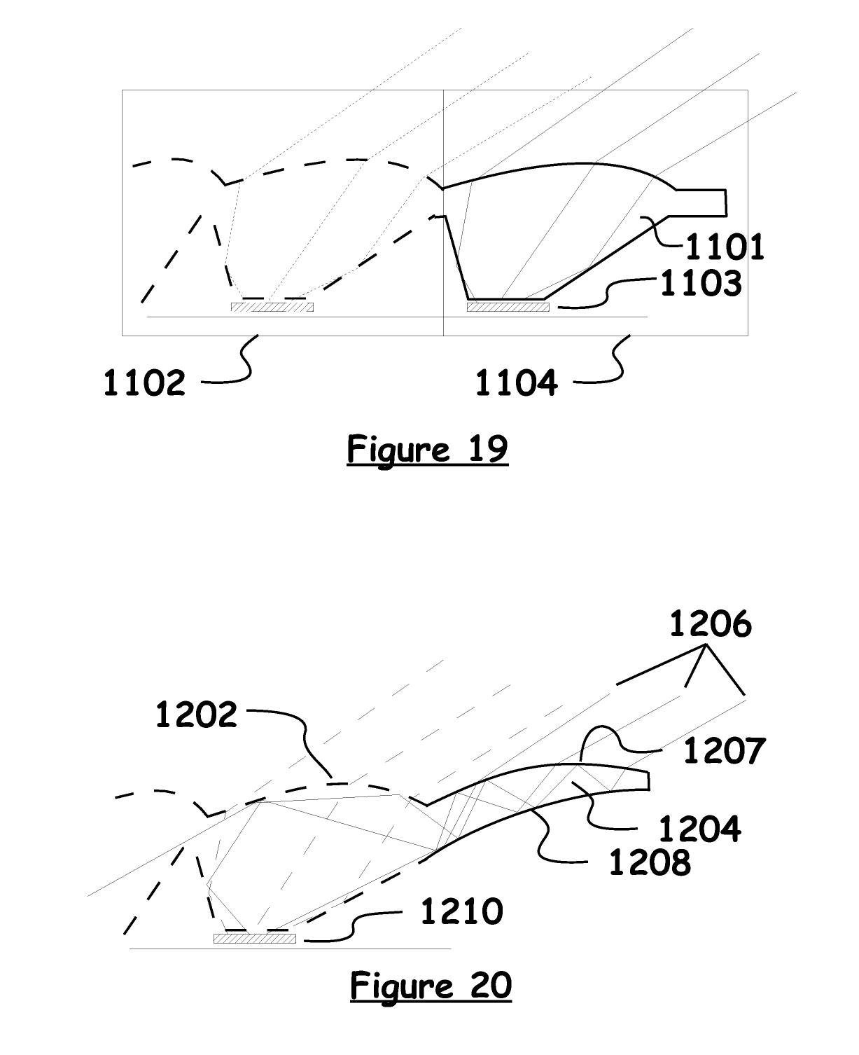

FIG. 19 shows one embodiment of a method of increasing the angular tolerance of a monolithic receiver. Region 1102 shows marginal rays in a nominal pointing position entering a nominal outermost ring of cells, including optical element 1101 and energy conversion cell 1103. While including additional materials for the perimeter cells and extra substrate, this approach imparts substantial tolerance to pointing errors with a relatively simple design. The extra row of cells can be substantially similar to the adjacent row.

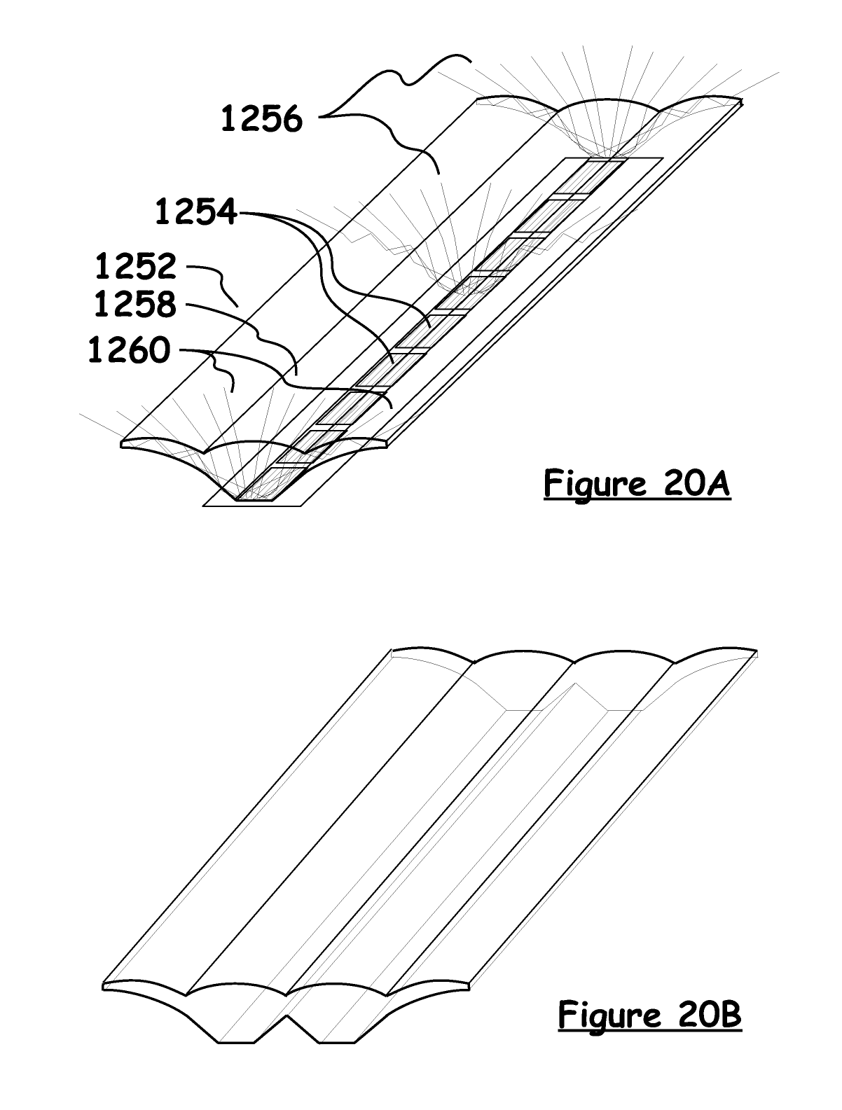

FIG. 20 shows an alternative embodiment of a method to recapture rays that would otherwise be lost at the periphery of the receiver 112 due to pointing errors. In FIG. 20, rays 1206 that are offset due to tracking errors and would miss perimeter cell 1202, enter structure 1204 that is an extension of the secondary optic. The offset rays 1206 enter the first surface 1207 of structure 1204 and are initially refracted toward the second surface 1208. Subsequent reflections by TIR by both the first and second surfaces of structure 1206, guide the rays 1206 toward energy conversion cell 1210 and/or adjacent cells.

FIG. 20A shows the embodiment of FIG. 20 adapted to use with linear primary concentrators such as reflective troughs. Energy conversion cells 1254 are deployed in a linear ray aligned with the axis of the primary collector and proximate to the linear focus of said collector. The secondary concentrator 1252 receives rays 1256 from the primary collector. One class of rays are incident along the center portion of the secondary collector 1258 and are further concentrated and distributed by a refraction in the first surface and subsequent reflections in the TIR second surface. A second class of rays are incident on the extensions 1260 and are refracted by the first surface and subsequently reflected by TIR by the second surface and again by the first surface. Subsequent reflections by TIR by both the first and second surfaces of structure 1260 guide the rays toward one of the energy conversion cells 1254.

FIG. 20B shows an embodiment similar to FIG. 20A but with two prismatic TIR surfaces and two corresponding refractive first surfaces which can be used with a double row of energy converging cells. The additional row of conversion cells and the corresponding optical surfaces permits a greater collection angle and/or more angular tolerance to the rays incident from the linear primary collector. This technique can be extended to multiple linear rows of cells, for example but not limited to 3 rows of cells, 4 rows of cells and so on.

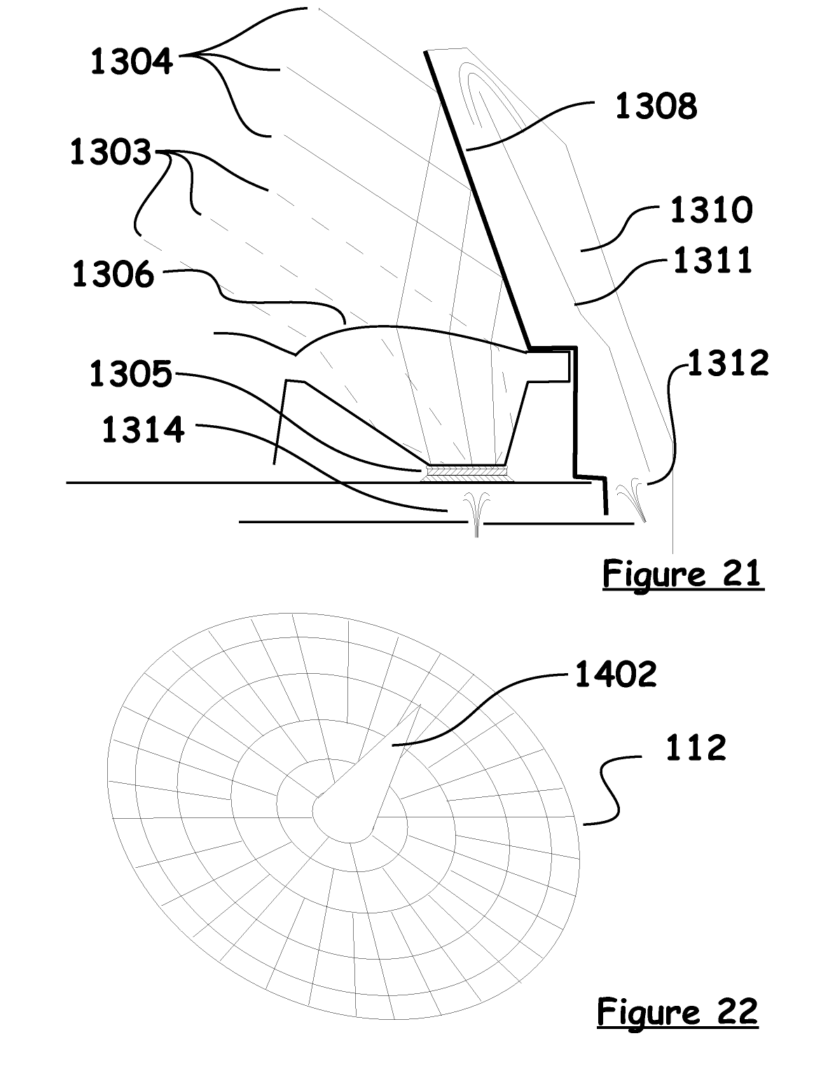

FIG. 21 shows an embodiment of an alternate method to recapture rays at the periphery of the receiver due to errors in tracking or focus or aberrations in the primary collector. This method may be suited to systems where the receiver is positioned after focus and the receiver is in a ray bundle that is substantially divergent.

In the embodiment of FIG. 21, rays 1304 that would normally miss element 1306, and therefore energy conversion cell 1305, would be lost, are instead reflected by additional reflective element 1308. Rays 1304 that are reflected by reflective ring 1308 are redirected into optical cell 1306 and as a result refracted and reflected to energy conversion cell 1305 and thus recaptured.

Suitable materials for reflective ring 1308 include polished stainless steel and polished aluminum. The reflectance may be enhanced by coatings or platings such as aluminum or nickel, in which case the ring may be made from a less reflective material such as steel or copper.

Due to the high irradiance from the primary concentrator at this position, cooling of the ring 1312 may be necessary to prevent degradation of the reflective surface or damage to the substrate. In this embodiment, a liquid coolant jacket 1310 with baffle 1311 is deployed and is coupled to receiver cooling system 1314.

The design of the refractive and reflective surfaces of optical element 1306 may simultaneously consider the direct rays 1303 and the reflected rays 1304, and the angle of reflective ring 1308. Another class of rays may be recaptured at the center of the receiver.

Specifically, due to the radial layout of the cells 1305, it can be difficult to extend the cellular structure of the receiver to the center to capture rays that may be incident there from the primary optic. Rays may be incident in this area due to pointing errors, or due to distortions or aberrations in primary optic.

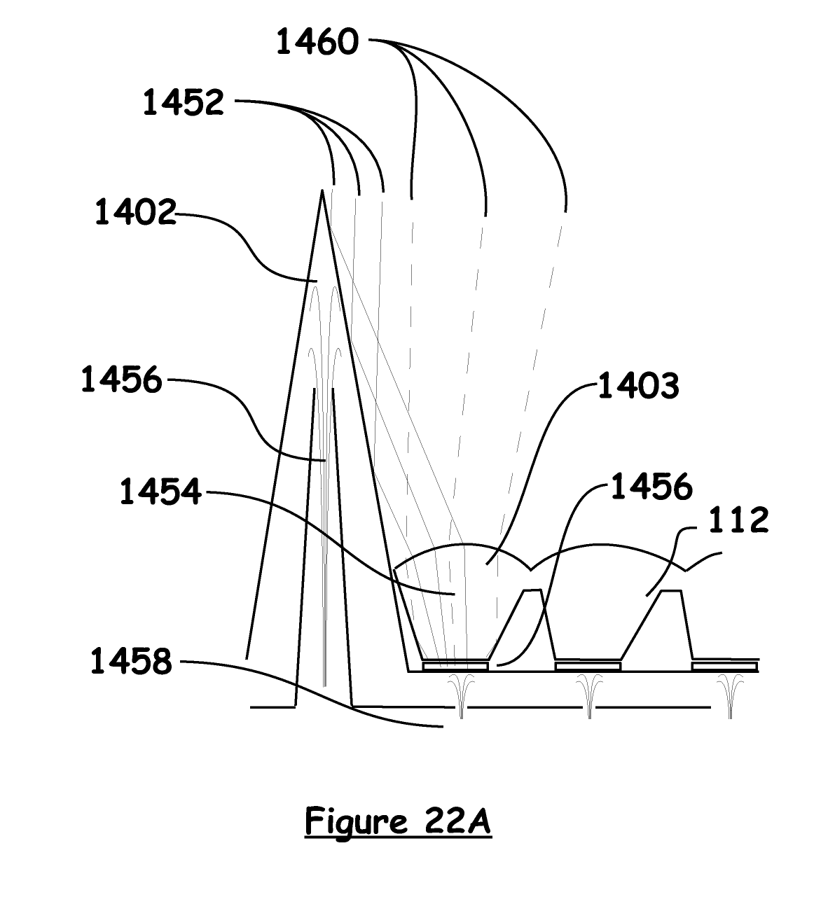

Accordingly, FIG. 22 shows a device 1402 for redirecting rays incident at the center of receiver 112 onto active cells of the receiver 112. Device 1402 is a protrusion from receiver 112, generally circularly symmetric and in the form of a cylinder, a cone, a truncated cone or a prism with a reflective surface. In certain embodiments a cylinder may be tapered, either in a direction toward or away from the receiver.

FIG. 22A shows the operation of the central reflector 1402 in cross section. Rays 1452 that would normally miss receiver 112 are incident on the reflective surface of central reflector 1402. These rays are reflected into an optical cell 1403 of receiver 112 and directed onto energy conversion cell 1456.

Suitable materials for central reflector include metals such as aluminum, stainless steel, and copper and cast or polished glass. The reflective properties of central reflector 1402 may be enhanced by polishing the base metal, acid dipping, metal platings and/or evaporative coatings.

For systems with a high-concentration primary 111 metals may be preferred to dissipate the optical energy that may be absorbed and result in heating of the central reflector 1402. As a result, it may be beneficial or necessary for the central reflector 1402 to be in thermal communication with the receiver 112.

For example, the central reflector 1402 may be made of solid metal in contact with the metal substrate of receiver 112. In an alternate embodiment shown in FIG. 22A, central reflector 1402 is cooled by a suitable liquid flow 1456. In some embodiments this may be part of the same liquid cooling system 1458 that is used to cool receiver 112.

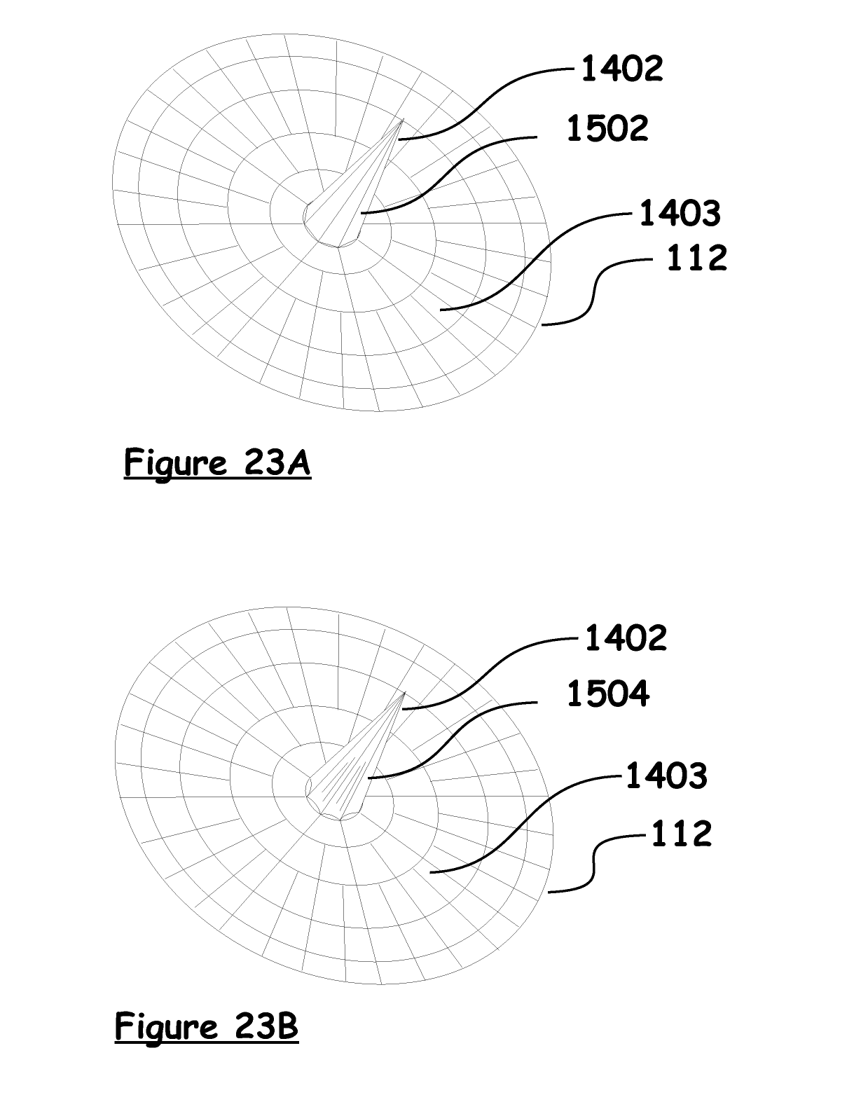

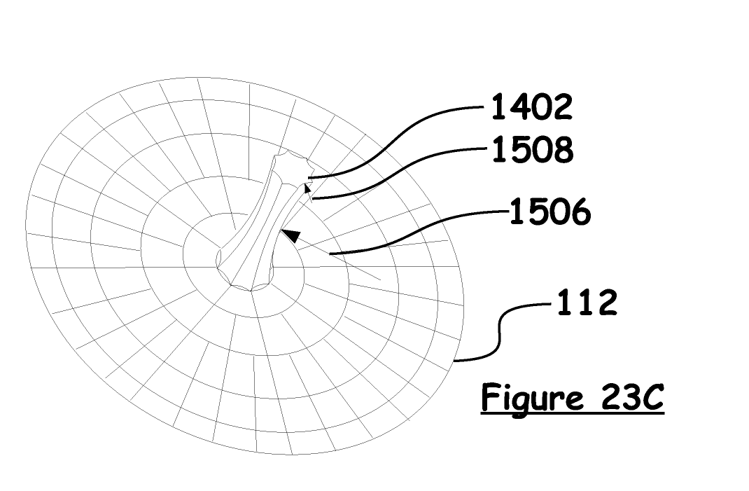

FIG. 23A shows an alternate embodiment of central reflector 1402, where the reflector is comprised of flat planes 1502 to limit dispersion upon reflection by a convex surface. This may be done as highly dispersed rays could be difficult to recapture efficiently with optical cells as represented by cell 1403. In certain embodiments, the planes 1502 of central reflector 1402 are aligned with the radial rows of cells 408 in receiver 112.

FIG. 23B shows an alternate embodiment of central reflector 1402 similar to embodiment of FIG. 23, except that the planes 1502 are replaced by concave flutes 1504. As in the embodiment of FIG. 23A, in some embodiments the flutes may be aligned with the radial rows 408 of receiver 112. The curvature of flutes 1504 are a design parameter that can varied and optimized together with the angle of the flute and the optical cells 1403 of receiver 112, to best capture both direct rays 1460 and rays 1452 redirected by central reflector 1402.

FIG. 23C shows an alternative embodiment of an apparatus performing optical compensation by a reflective protrusion from a center of the receiver. In this embodiment the reflective protrusion has a curvature in the axis of the protrusion 1506, and also has curvatures 1508, concave planes, across the axis of the protrusion as in the embodiment of FIG. 23B. A structure having curvatures in both axes is hereby referenced as a compound-curved protrusion.

FIG. 23C thus shows an alternate embodiment of central reflector 1402 with a curvature along the axis which may be employed separately or in combination with the planes of FIG. 23A or the flutes of FIG. 23B as is shown. Also shown in FIG. 23C is a central reflector with a minimum diameter that could be used to introduce or exhaust a cooling medium and or a structural element.

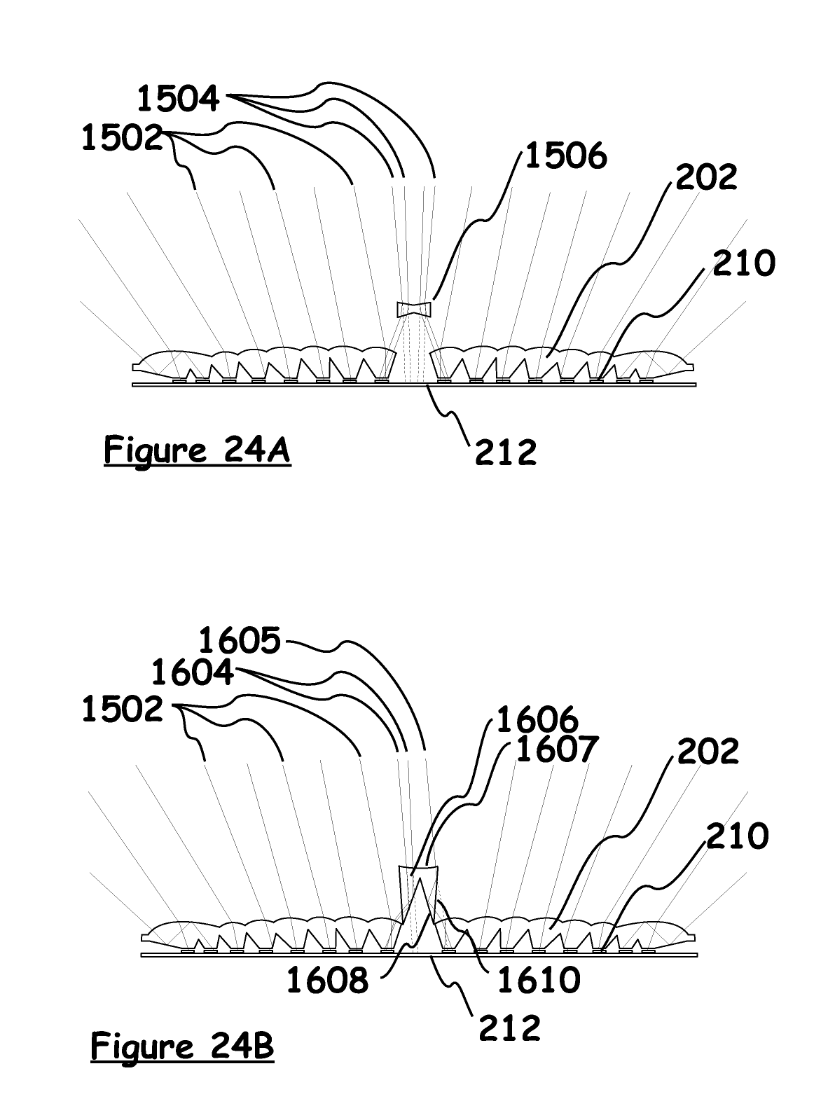

FIG. 24A shows an embodiment which allows recapture of rays at the center of the receiver. Specifically, rays 1504 would ordinarily strike the center of the receiver (dashed lines) lacking optical elements 202 such as lenslets or corresponding energy conversion cells 210. These rays may be incident to the center region owing to tracking errors and/or specific properties of the primary optic. As the optical energy of rays 1504 would be incident to the center portions, that optical energy would be converted to heat and lost.

According to the embodiment of FIG. 24A, however, divergent element 1506 redirects rays 1504 to optical elements 202 and the corresponding energy conversion cells that are adjacent to the center. Divergent element 1506 may be diffractive, holographic, or refractive in nature, and exhibits the characteristics of a negative lens.

In an embodiment such FIG. 24A, the divergent element 1506 is an axicon—a refractive lens with a conical surface or surfaces, or the diffractive or holographic equivalent. In certain embodiments the axicon is a negative refractive axicon with one or two concave conical surfaces that refract rays away from the inactive center of the receiver, toward active cells proximate to the inner annulus of the receiver.

Curvatures and/or angles of the surfaces of the divergent element 1506 may be varied to satisfy the inputs from the primary optic and the characteristics of the receiver. In general, the divergent element and the receiver may be designed together.

The divergent element 1506 works together with the optical elements of the secondary optic, and in some embodiments they may be made together as one piece with the receiver. In other embodiments however, it may prove advantageous to manufacture these components as two or more separate pieces, and then to hold the divergent element 1506 in suitable optical alignment using appropriate structural elements.

FIG. 24B shows an alternate embodiment of an apparatus configured to recapture rays incident at the center of the receiver. Again, rays 1604 and 1605 would ordinarily strike the center of the receiver (dashed lines) lacking optical elements 202 or corresponding energy conversion cells 210, and thus the optical energy of those incident rays would be converted to heat and lost. The rays may be incident in this central region due to tracking errors and/or due to specific properties of the primary optic.

In the specific embodiment shown in FIG. 24B, however, divergent element 1606 redirects rays 1604 and 1605 to optical elements 202 that are located adjacent to the center and to the corresponding energy conversion cells. Divergent element 1606 uses both refraction and total internal reflection, to redirect rays from the center of the receiver to the active areas of the receiver.

In certain embodiments such as that shown in FIG. 24B, the top surface 1607 is a negative refraction surface. In some embodiments this negative refraction surface may be a negative axicon.

In certain embodiments, both the inner surface 1608 and the outer surface 1610 are conical and may contribute to control of the rays by TIR. For example, rays 1604 enter divergent element 1606 and are refracted by surface 1607 and subsequently reflected via TIR on surface 1608 at sufficient angle to be transmitted by and refracted by surface 1610 and incident on an active cell 202 of the receiver. Similarly, ray 1605 is refracted through surface 1607 and reflected by TIR from surface 1610, and reflected again by surface 1608, after which it is transmitted and reflected by surface 1610.

The curvatures and/or angles of surfaces 1607, 1608, and 1610 of divergent element 1606, may be varied to satisfy the inputs from the primary optic and the characteristics of the receiver. In general, this divergent element may be designed together with the primary optic and the receiver.

Divergent element 1606 works together with the optical elements 202 of the secondary optic, and may be made together as one piece with that structure. However, it may prove more advantageous to manufacture the two structures as separate pieces, and then to hold the divergent element 1606 in suitable optical alignment with the receiver and overlying secondary optic utilizing suitable structural elements.

FIG. 25 shows an alternative embodiment of a secondary optical compensator suited for lower concentration ratios, comprising a first refracting surface having lenslets 204 as described with reference to FIG. 10A and a second planar refracting surface 1702.

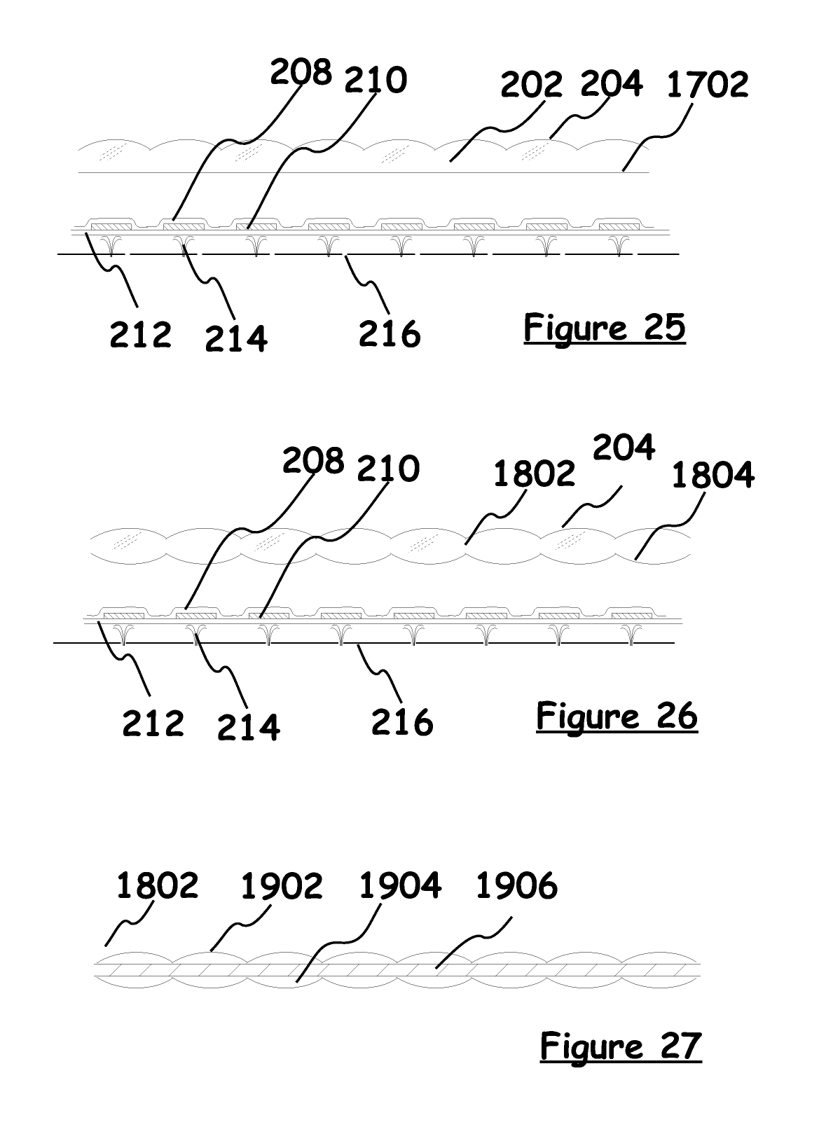

FIG. 26 shows an alternative embodiment of a secondary optical compensator 1802 suited for intermediate concentration ratios, comprising two refracting surfaces, a first refracting surface 204 and a second refracting surface 1804, wherein both surfaces include lenslets.

FIG. 27 shows a secondary optical compensator 1802 comprising a flat glass element 1906 having optical features 1902, 1904 on one or both sides, that is co-molded or otherwise attached and formed from a suitable molded polymer such as silicone.

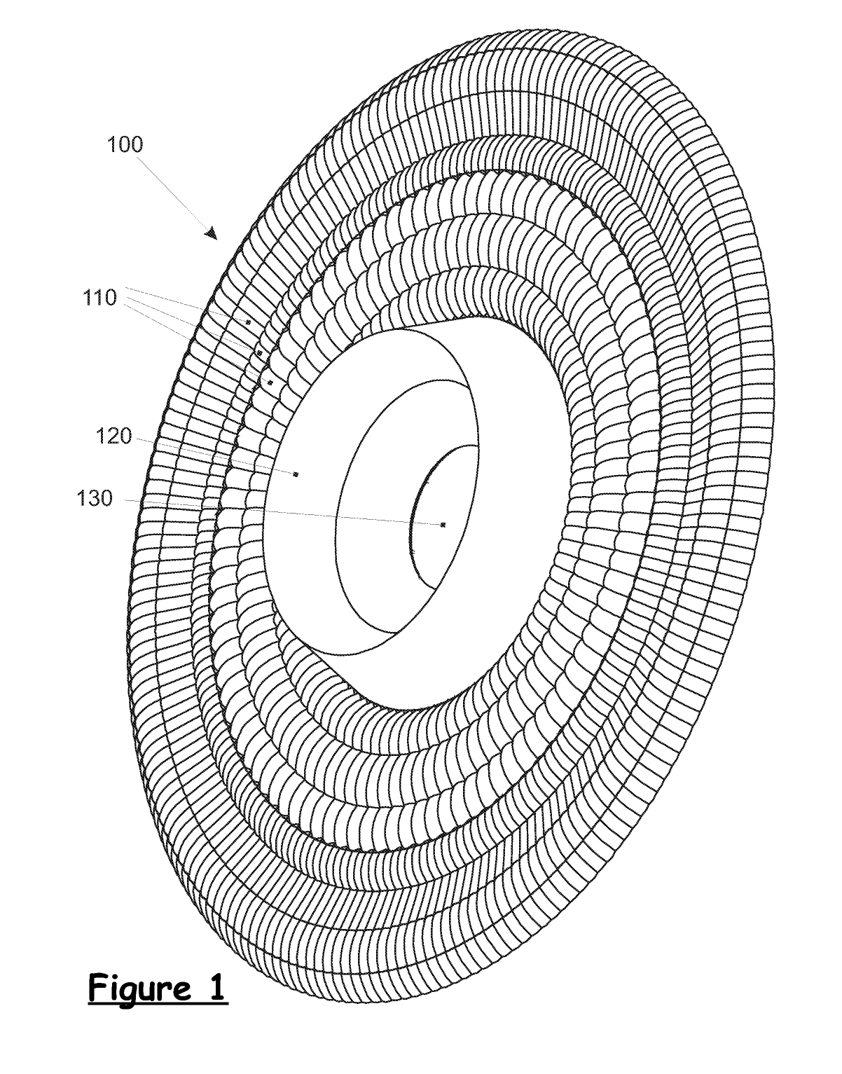

FIG. 1 shows an oblique view of the front surface 100 of a monolithic secondary optic according to an embodiment of the present invention. The front surface 100 bears an array of refractive lenslets 110. Near the center, a raised portion 120 captures highly oblique rays, which in combination with shading of the primary concentrator by the receiver and optic, produces a central zone 130 that is free of concentrated light at modest amounts of mispointing. This embodiment achieves passive optical compensation with significant additional concentration using a monolithic, minimum-glass, castable structure.

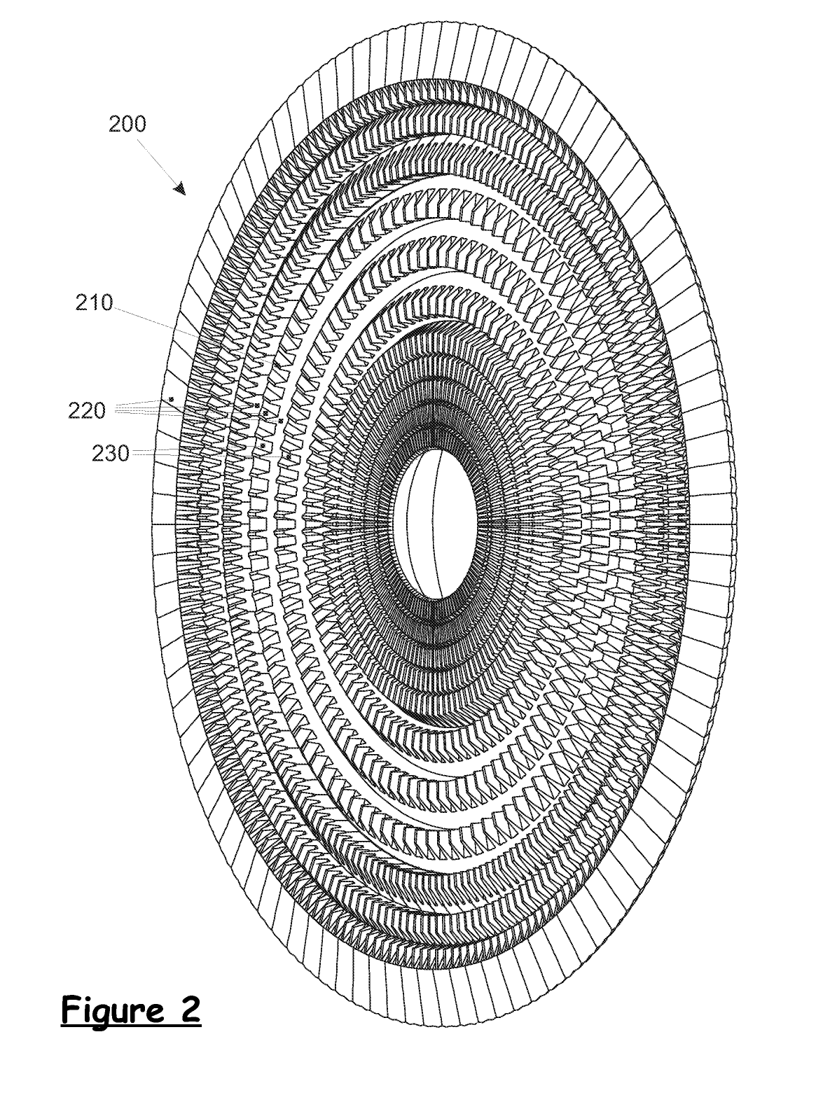

FIG. 2 shows an oblique view of the back surface 200 of the monolithic secondary optic shown in FIG. 1. The tips of the projections, e.g., 210, are in contact either directly, or via an index-matching material such as a silicone or silica gel, oil, or fluorinated polymer oil or gel, optical adhesive or the like.

Surfaces, e.g., 220, including the outer rim of the optic and the side walls of the projections are used for TIR. The projections are therefore TIR concentrating light pipes that lead to individual cells. Certain surfaces (e.g., 230) are non-critical, since light is directed away from them by the front refractive surfaces.

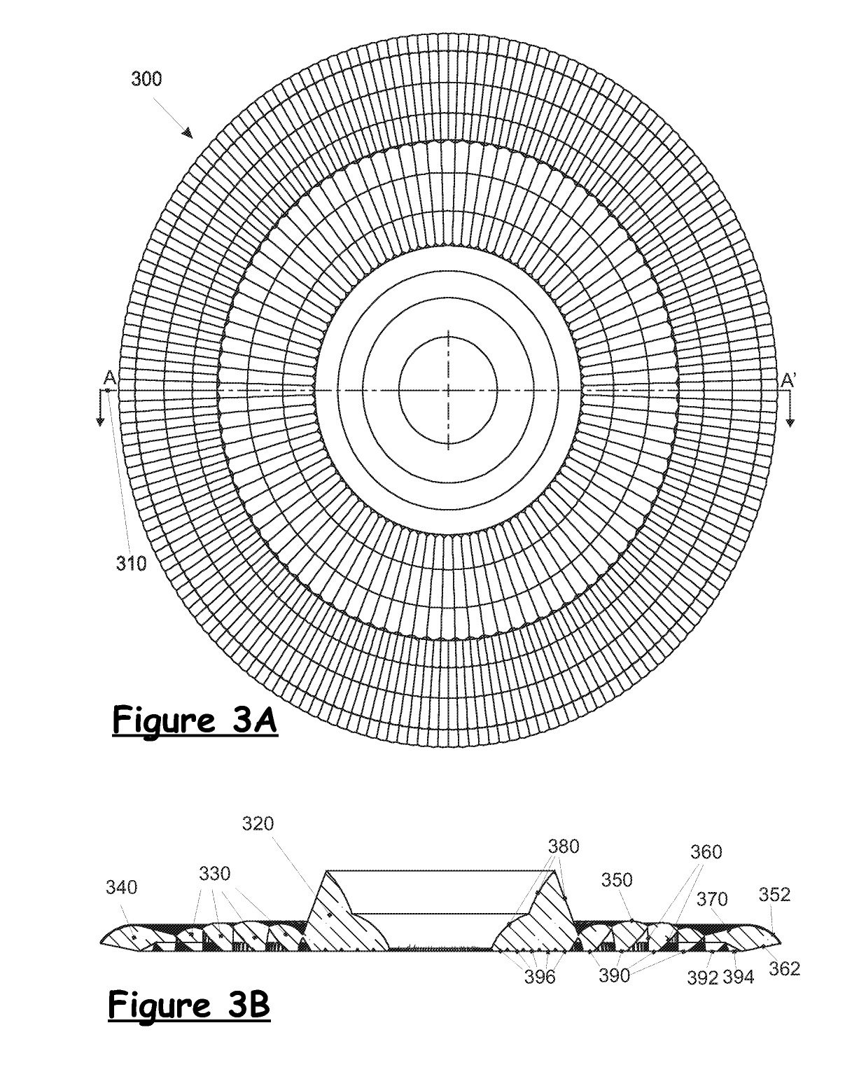

FIG. 3A shows a top view of the optic in FIGS. 1 and 2. Reference number 310 shows the location of the line from which the section view in FIG. 3B is generated.

Element 320 is a thick optical element intended to capture highly oblique rays via refraction and TIR. This element can alternatively be replaced with a separate ring lens/prism that directs light down to additional rows of lenslets (e.g., 330), if the requirement for monolithic structure of the device is relaxed.

In the interior region, refractive lenslets 330 focus light into high-aspect-ratio rectangular areas that are directed down individual TIR light pipes. Region 340 is a passive optical compensator that directs light radially inward via refraction and two TIRs. Surfaces 350 are refractive only, designed with a circumferential radius such that incident light focuses near the surfaces 390 and a radial curvature to ensure light does not escape TIR on surfaces, e.g., 360, which operate in TIR only.

Light landing on region 352 is focused both radially and circumferentially. The light reflects off the rear surface 362 then reflects off surface 370 down to the surface 392. The circumferential curvature of 352 is designed so that the reflection off the circumferentially curved surface 370 results in a circumferential focus near the surface 392. The circumferential curvature of 370 is designed such that incident light is refracted circumferentially to a focus near the surfaces 392 and 394.

Surfaces 380 act as refractors of incident rays and TIR reflectors of oblique light that enters the opposite side, directing light downward toward surfaces 396. These surfaces may in general be scalloped or contain recesses to channel light into circumferential bands. However, a more effective way to perform additional circumferential concentration is to use a separate ring optic and take advantage of the additional degrees of freedom afforded by the additional refractive and/or reflective surfaces.

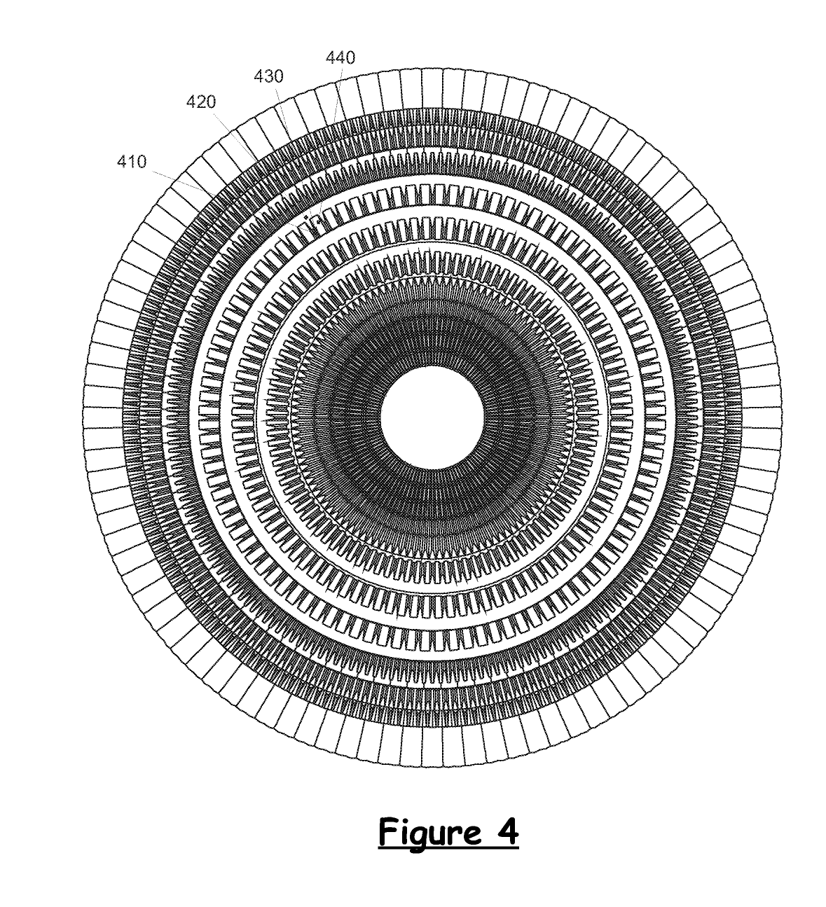

FIG. 4 shows a bottom view of the optic in FIGS. 1-3. Element 410 is in optical communication with an energy converter, e.g., solar cell. Element 420 is a TIR surface used for radial light guiding and concentration. Element 430 is a TIR surface used for circumferential light guiding and concentration. Element 440 is a non-critical surface that does not receive concentrated light.

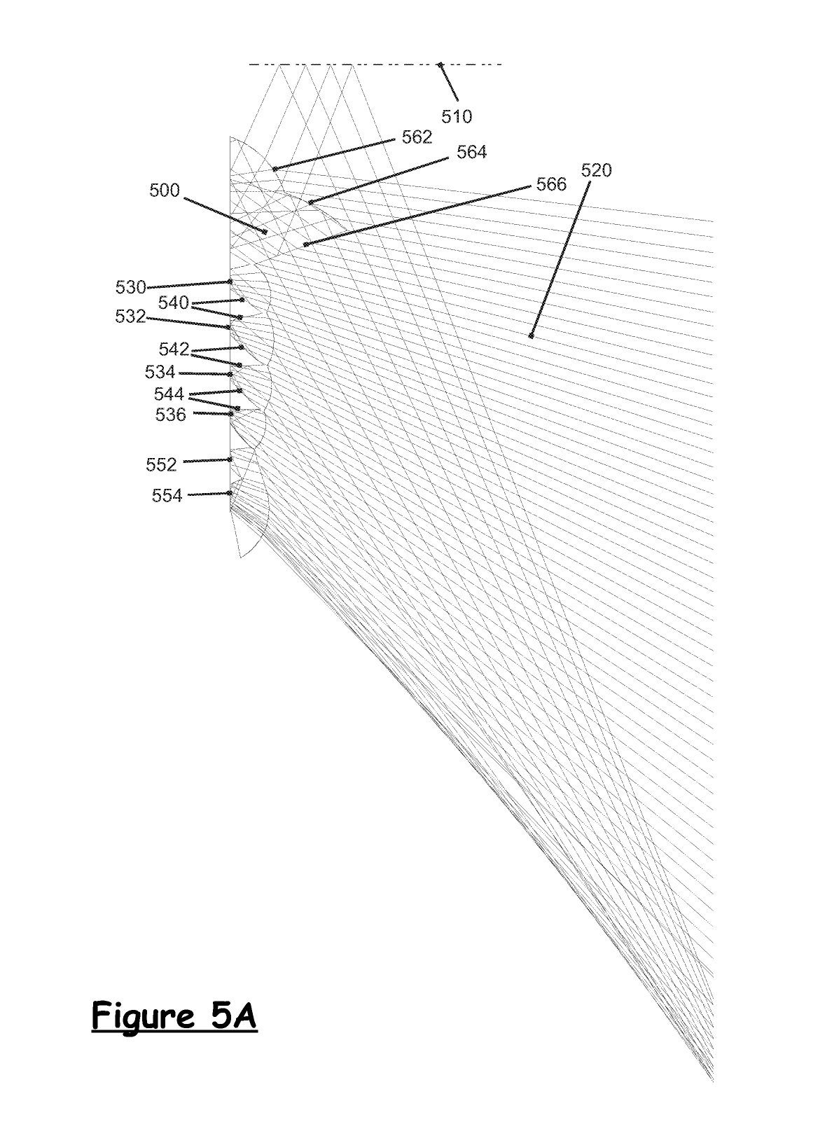

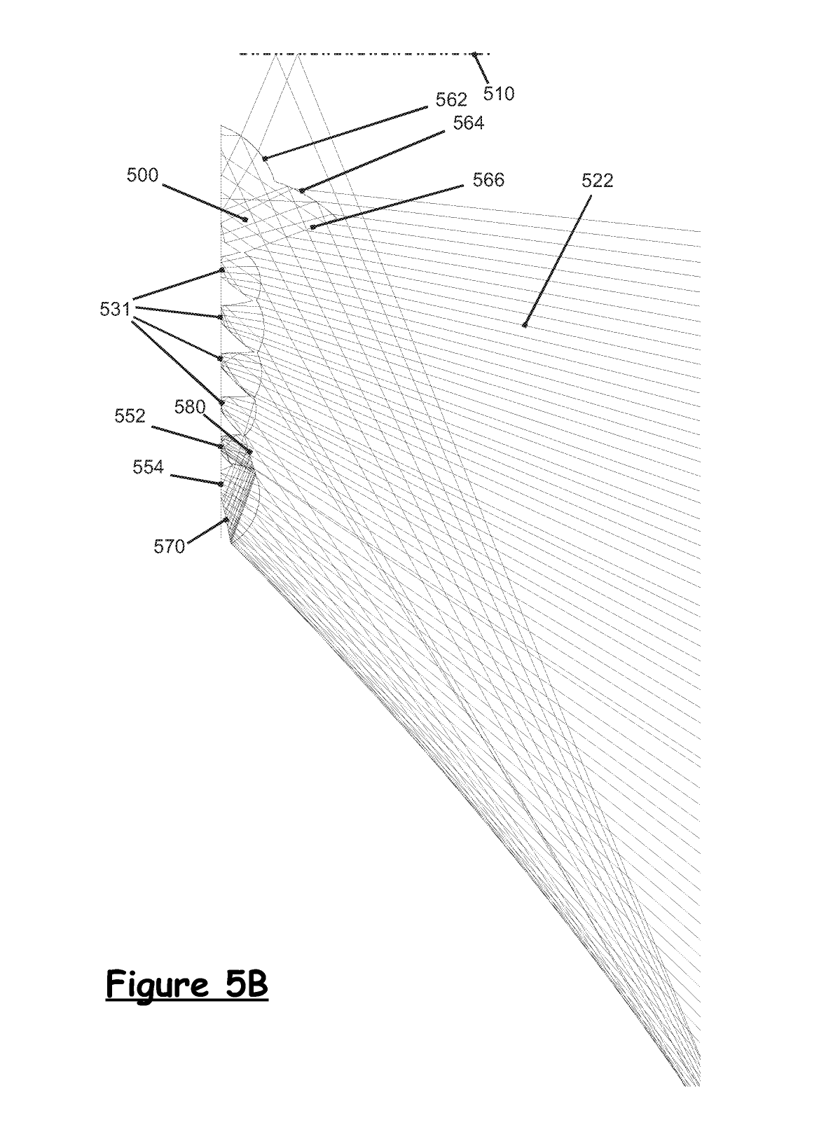

FIG. 5A shows a ray trace of the radial operation of the optic 500 in FIGS. 1-4. Item 510 is the axis of symmetry of the optic. The lines 520 are incident rays coming from a fast and highly aberrated primary concentrator (on the right but not shown here). Rays apparently reflecting off the center line are those arriving from the opposite side of the primary concentrator.

Regions 530, 532, 534, and 536 are absorbers whose irradiance is relatively constant with modest amounts of mispointing. In certain embodiments, the magnitude of the irradiance of these regions is controlled by adjusting the circumferential and radial extent of their corresponding front-surface refractors to facilitate efficient series electrical interconnection of strings.

Surfaces 540, 542, and 544, are radial TIR concentrators and light pipes. Surfaces 552 and 554 are absorbers that receive portions of the light falling at the outer edge of the optic.

Light incident on surface 562 near the direction of the axis of symmetry 510 refract directly to the back absorbing surface. Light incident obliquely is refracted toward the back surface.

Some of the rays reach the back surface after bouncing by TIR off surface 566. Vice versa, light striking 566 obliquely refracts downward and some requires a TIR reflection off 564 to reach the back surface.

FIG. 5B shows a ray trace in which the primary concentrator/secondary optic pair is rotated by 0.75 degrees counterclockwise from ideal. This rotation produces a significant translation of the location of incidence of the rays on the optic, most markedly seen at the inner and outer edges. Light refracting onto surface 570 bounces by TIR onto surface 580, which bounces light to surface 552. That portion of the lobe had propagated to surface 554 in FIG. 5A. Light landing on surfaces 531 is relatively unaffected.

FIG. 5C shows a ray trace in which the primary concentrator/secondary optic pair is rotated 0.75 degrees clockwise from ideal. With this rotation, no light lands on surface 570. Some of the light at the edge of the lobe is reflected via surface 548 to 554. Some light refracts directly to 552. Again, the regions 531 are relatively unaffected.

This condition sets the requirement for the height of the surfaces 564 and 566. Again both these surfaces play the dual roles of refraction and total internal reflection.

Alternate geometries based on a non-monolithic secondary optic provide degrees of freedom that can significantly reduce the broad distribution of ray directions in the volume between surfaces 564 and 566, better preserving the ability to use non-imaging concentration in this region and providing better optical compensation.

The design of a multicellular monolithic secondary optic likely represents a complex multi-variable optimization problem that is significantly more complex than the standard problem of a single channel solar collection system or the capture of LED emissions, or other typical problems known in the art. Accordingly, embodiments of the present invention include a systematic methodology to design embodiments of secondary optics structures.

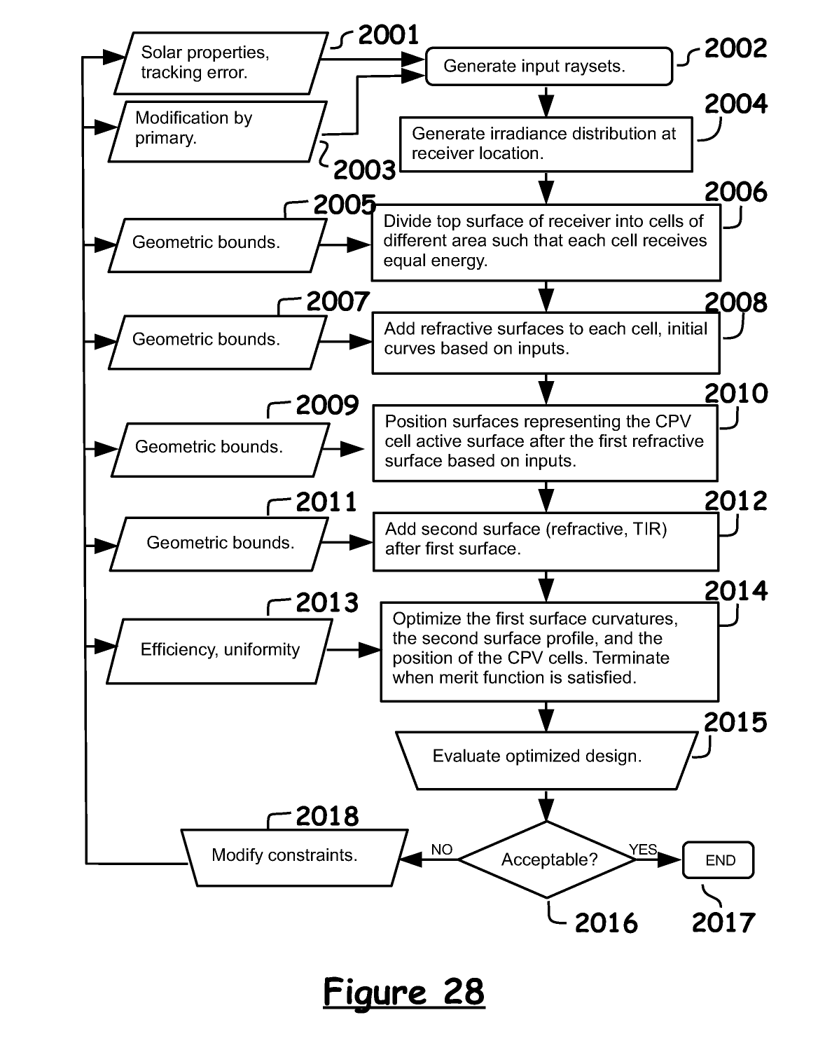

FIG. 28 shows a simplified flowchart for one embodiment of such a design methodology. A first input 2001 to the design method are the rays of the sun and certain properties of the tracking system. This includes solar irradiance properties such as intensity, spectrum, and angular subtense. This input may be generic, or may be tailored for a specific country, territory or even a particular location. This input may include daily and seasonal variations in power and spectrum. Such data is available from a large body of work including published work by US government agencies such an NASA and NREL.

In an embodiment, the angular subtense of the sun (nominally accepted to be 0.526 degrees or 31.6 arcminutes) is modified by the pointing error (also know as the tracking error) of the tracking system dynamically pointing the solar energy collection system toward the sun as it transits the sky. In certain embodiments, the rays representing the pointing error are weighted according to the likelihood of the error occurring during operation. For example large errors may be expected to occur over a small portion of the overall operational time of the system and receive a smaller weighting, as compared with small errors that may be accepted as falling within the normal operational parameters of the system.

In summary, the rayset may comprise nominal solar properties such as power and spectral content, modified by daily and seasonal variations for a region or a specific location, optionally further modified by aerosol content of the atmosphere in a particular region or location, and modified by the pointing accuracy of the system with each variation being suitably weighted proportional to the relative expectation of occurrence.

The raysets originating from the sun and optionally modified by regional or local atmospheric conditions, and modified by the measured or predicted properties of the tracking system, can be further modified by the properties of the primary in step 2003. The optical properties of the primary concentrator, for example the refractive or reflective properties, may be determined from mathematical models and/or direct measurement and used to modify the ray set generated in from the data in step 2001.

In general, data from the primary optic will modify the direction and relative intensity and spectrum of the rays. In certain embodiments, several versions of the primary optic are used to generate a modified ray set. Each version of the primary optic may represent a variation of the nominal primary optic due, for instance, to unit to unit variations that occur as a result of manufacturing tolerance or variation over a nominal unit as may occur over its useful lifetime.

Each version of the primary may be weighted in proportion to its likelihood of occurrence, either predicted and/or measured. As a result a rayset may be generated having a relative number and/or a relative power of the rays modified according to a weighting factor.

This data becomes input for method subsequent steps 2004 and 2014. In certain embodiments, the raysets are generated once and stored in a table to speed up subsequent ray traces and design optimizations, for steps 2004 and 2014.

In step 2004, the raysets generated in step 2002 are traced to a surface located by a mathematical model at the intended location of the receiver. The spatial distribution of the irradiance at said surface may be calculated based on relative intensities of the rays generated in step 2002 and incident on said surface.

An optical engineer may determine a number of rays to trace, that represents a trade off between achieving a statistically valid estimate of the irradiance distribution at said surface, and efficient design-cycle times. A number of approximately one million rays may be sufficient, although a smaller number may be used in the initial phases of the design. Said irradiance distribution should be representative of the lobe. Validation of the model can be accomplished by comparison of the model data to measured data.

Once a representative irradiance distribution has been determined at the receiver location, and optionally validated by comparison to measured irradiance distributions, in step 2006 the surface of the receiver location is divided into cells of nominally and substantially equal irradiance. Such division of this surface into areas of substantially equal irradiance may influence subsequent steps in the process.

A number of factors can play into this step of division into areas of substantially equal irradiance. Examples of such factors include but are not limited to the geometric bounds specified by the optical engineer, and the size of the receiver (for example a diameter), voids in the bounds (such a central hole diameter and position), the number of cells, the desired concentration factor, the energy conversion cell dimensions, and the geometry of the cells.

According to alternative embodiments, in step 2006 the receiver may be divided into cells of predetermined relative irradiance. Such dividing may account for maximum peak intensities as may occur under less than optimal lobe profiles encountered under a range of operating conditions. The division of the receiver into cells may facilitate passive electrical compensation.

It may be desired that the cells have a tessellating property to minimize any inactive areas between adjoining cells. However, it is not necessary that all cells be self similar.

In certain embodiments, cells may be laid out in a ring and spoke pattern. Such a pattern satisfies a requirement for efficient tessellating geometry, and allows sufficient design variables to achieve both optimal energy distribution as determined in step 2006, and individual cell optimization as performed in step 2014. Said geometry also possesses a strong resemblance to the geometry of the cells, which may generally be constrained to square or rectangular geometries according to the limitations of conventional wafer singulation techniques (such as sawing). Thus a tessellating hexagon geometry may be used, but would require more exotic singulation techniques.

Thus factors other than as optical considerations of the receiver (such as efficiency) and the desire for additional devices to aid in energy capture may be considered in determining a cellular geometry of the receiver. Examples of such other factors include but are not limited to manufacturing considerations such as the possibility of producing components of said receiver (notably the secondary optic) in self-similar segments that may be produced from a common tool and later assembled into the whole.

In certain embodiments, an annular secondary optic is subdivided into self-similar radially-divided segments, with tooling produced for only one segment and multiple units of said segment assembled into a full secondary optic. A possible benefit of this approach is significant reduction in tooling costs and time to market. Such an approach can be enacted if the initial geometry selected by the optical designer permits such segmentation. For example, geometry comprising a prime number of radial cells may not lend itself of said partitioning.

After the receiver has been partitioned into cells of equal irradiance in step 2006, initial refractive surfaces are ascribed to first surface each cell. These surfaces are generated in step 2008 given the input geometric bounds 2007 including the basic layout.

For example low concentration cells may comprise one or two refracting surfaces, whereas higher concentration cells typically include a first refracting surface followed by a total internal reflecting tapered light pipe. Geometric bounds include a starting value and limits on the maximum and minimum thickness of the secondary optic, starting values and limits on curvature in a particular axis. A potentially favorable starting point for the top refractive surface, would be a set of curves (one for the radial axis and in general a different one for the circumferential axis) that yield a focal length equal to the starting thickness.

After the first surface curvatures have been assigned in step 2008, it may generally be advantageous to add surfaces representing the active areas of the energy conversion cells using geometric constraints 2009. Said constraints include the dimensions of said cells, the location of the plane containing said surfaces, and a starting position for each surface.

In certain embodiments an initial position for each cell surface may be hard-coded. Alternatively, in certain embodiments a raytrace of rays 2002 or a subset thereof through the surfaces defined in step 2008 will yield an area of maximum intensity for each cell. The center of this area may represent a good starting point for the position of each cell surface. A function of such cell surface is to collect the ray data for rays incident on the surface, and to compute irradiance values such as total energy and uniformity of energy distribution for each surface.

After the cell surfaces have been initially placed in step 2010, the initial second surface of the primary optic is added in step 2012 according to the geometric bounds of step 2009. Geometric constraints in step 2009 can include maximum and minimum angles on the tapers. The latter may be constrained by minimum draft angles permitted for hot-molding or hot stamping, and the size and shape of the active area of the energy conversion cells.

A possible initial starting value for the TIR taper may be to add the minimum thickness to the top surface, and then connect the top surface to the exit aperture. In general, the exit aperture has the same shape and dimensions as the active area of the energy conversion cell, and is in a plane a short distance above the top surface of the energy conversion cells.

At the end of step 2012, the full optical element of the receiver is modeled along with the collection surfaces representing the active areas of the energy conversion cells. This model is a starting point for further design and may have sub-optimal performance.

Some or all of the surfaces constructed in this manner will be bounded variables in an algorithm implemented on a digital computer. One or more of the variables can be varied, and the effect of these variations evaluated based on a merit function. Such a merit function may use as inputs, the properties of the rays incident on the secondary optic (for example total power), and the properties of rays incident on the surfaces representing the energy conversion cells (including for example total power, uniformity of power per cell among all of the cells, and uniformity of intensity within each particular cells).

The total power incident on all cell surfaces, divided by the total power incident on the receiver, is a measure of the secondary optic efficiency. Efficiency and uniformity, both between cells and within each cell, can be the principal elements of the merit function and can be ascribe weights according to importance by the optical engineer.

In step 2014 the variables are varied in a controlled fashion, and the results are measured against the merit function and the variables varied again depending on the merit function change. Thus if the merit function improves the variables are further adjusted in the same direction: otherwise, the variables are further adjusted in the opposite direction. If the change in merit function falls below a predetermined threshold after several changes to the variable, in general that particular variable is fixed and another variable varied.

In particular embodiments such optimization techniques can be employed, including classes of non-linear optimization. In some embodiments the optimization method known as downhill simplex, and also known as Nelder-Mead optimization, can be used. Optimization methodologies are available in commercial ray-tracing programs such as ASAP from Breault Research and also FRED from Photon Engineering, both of Tuscon, Ariz.

In certain embodiments, initial geometries and raysets are modeled in one of the commercial programs, along with programs native to said commercial programs that include the set of variables, bounds on said variables, the merit function, and weights on the components of the merit function. The optimization algorithms are allowed to run until the merit function is satisfied with a predetermined tolerance, or variations in the design parameters result in improvements in the merit function beyond a predetermined limit, and/or a predetermined number of iterations have been performed. The latter is a fail-safe parameter that prevents the algorithm from iterating endlessly.

After step 2014 is completed, the optical engineer may evaluate the design in step 2016. In the early stages of the design cycle, this evaluation may be performed numerically using the computer model. In later stages of the design cycle, this evaluation may include making physical models and performing physical measurements.

If the design is judged to be acceptable, then this portion of the design is concluded. Otherwise, the constraints of the design may be adjusted. These may include some or all of the constraints described above in inputs 2001, 2003, 2005 . . . 2013, as well as additional constraints that may be imposed by the optical engineer. Examples of such additional constraints include but are not limited, to the material of the secondary optic and therefore the refractive index and optical dispersion of that material.

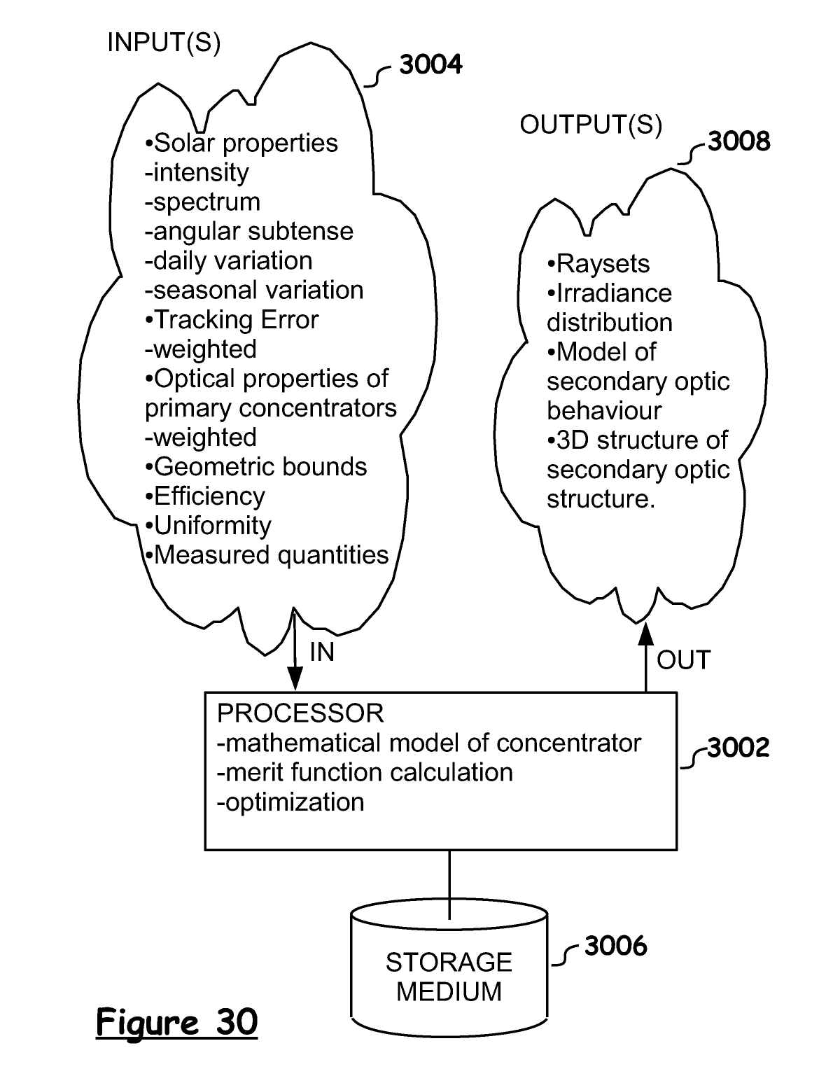

One or more of the steps of the process flow just described, may be performed utilizing a host computer system. As shown in FIG. 30, in certain embodiments the host computer system 3000 comprises a processor 3002 configured to receive an input 3004.

The processor 3002 is in electronic communication with a computer readable storage medium 3006. The computer readable storage medium has stored thereon, code configured to instruct the processor to perform certain steps of the process, to produce corresponding outputs 3008.

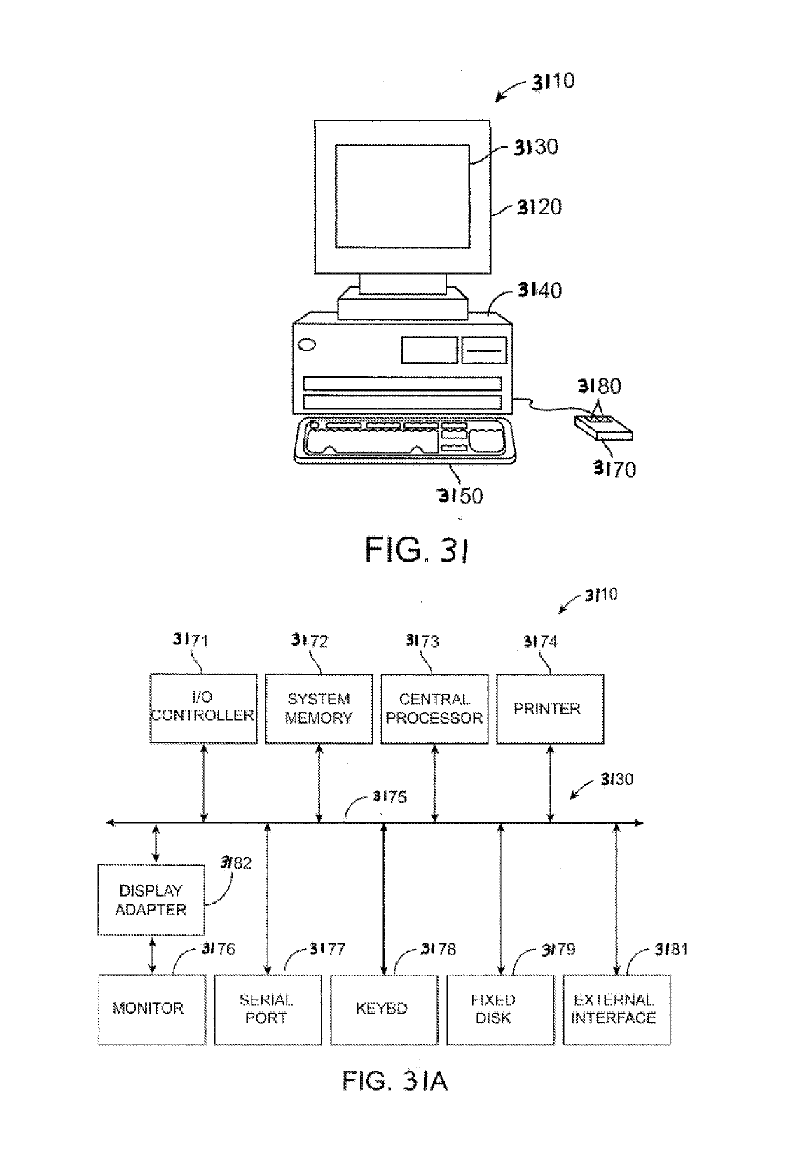

As described in detail above, embodiments of systems and methods according to the present invention are particularly suited for implementation in conjunction with a host computer including a processor and a computer-readable storage medium. Such a processor and computer-readable storage medium may be embedded in the apparatus, and/or may be controlled or monitored through external input/output devices. FIG. 31 is a simplified diagram of a computing device for processing information according to an embodiment of the present invention. This diagram is merely an example, which should not limit the scope of the claims herein. One of ordinary skill in the art would recognize many other variations, modifications, and alternatives. Embodiments according to the present invention can be implemented in a single application program such as a browser, or can be implemented as multiple programs in a distributed computing environment, such as a workstation, personal computer or a remote terminal in a client server relationship.

FIG. 31 shows computer system 3110 including display device 3120, display screen 3130, cabinet 3140, keyboard 3150, and mouse 3170. Mouse 3170 and keyboard 3150 are representative “user input devices.” Mouse 3170 includes buttons 3180 for selection of buttons on a graphical user interface device. Other examples of user input devices are a touch screen, light pen, track ball, data glove, microphone, and so forth. FIG. 31 is representative of but one type of system for embodying the present invention. It will be readily apparent to one of ordinary skill in the art that many system types and configurations are suitable for use in conjunction with the present invention. In one embodiment, computer system 3110 includes a Pentium™ class based computer, running Windows™ XP or Windows 7™ operating system by Microsoft Corporation. However, the apparatus is easily adapted to other operating systems and architectures by those of ordinary skill in the art without departing from the scope of the present invention.

As noted, mouse 3170 can have one or more buttons such as buttons 3180. Cabinet 3140 houses familiar computer components such as disk drives, a processor, storage device, etc. Storage devices include, but are not limited to, disk drives, magnetic tape, solid-state memory, bubble memory, etc. Cabinet 3140 can include additional hardware such as input/output (I/O) interface cards for connecting computer system 3110 to external devices external storage, other computers or additional peripherals, further described below.

FIG. 31A is an illustration of basic subsystems in computer system 3110 of FIG. 31. This diagram is merely an illustration and should not limit the scope of the claims herein. One of ordinary skill in the art will recognize other variations, modifications, and alternatives. In certain embodiments, the subsystems are interconnected via a system bus 3175. Additional subsystems such as a printer 3174, keyboard 3178, fixed disk 3179, monitor 3176, which is coupled to display adapter 3182, and others are shown. Peripherals and input/output (I/O) devices, which couple to I/O controller 3171, can be connected to the computer system by any number of approaches known in the art, such as serial port 3177. For example, serial port 3177 can be used to connect the computer system to a modem 3181, which in turn connects to a wide area network such as the Internet, a mouse input device, or a scanner. The interconnection via system bus allows central processor 3173 to communicate with each subsystem and to control the execution of instructions from system memory 3172 or the fixed disk 3179, as well as the exchange of information between subsystems. Other arrangements of subsystems and interconnections are readily achievable by those of ordinary skill in the art. System memory and the fixed disk are examples of tangible media for storage of computer programs, other types of tangible media include floppy disks, removable hard disks, optical storage media such as CD-ROMS and bar codes, and semiconductor memories such as flash memory, read-only-memories (ROM), and battery backed memory.

As used herein a “converter” can be an element that converts light energy into another form, e.g., electrical, chemical, or thermal or to a different electromagnetic frequency. Examples of converters include photovoltaic cells, thermolytic cells, pyrolytic cells, light absorbers, fluorescent absorbers, phosphorescent absorbers, quantum dots, and the like.

Some converters' conversion efficiency depends upon irradiance and irradiance profile, thus the converted power is not simply proportional to the incident power. Some photovoltaic converters, e.g., multiple junction cells produce power at a higher voltage and lower current than others, e.g., single junction cells. Some embodiments may connect cells that have different characteristics, e.g., single and multiple junction cells, in the same receiver. Cells having different efficiencies and characteristics may in some embodiments be coupled into compensating groups and serial or parallel strings. Coupling and connecting pre- and post-conversion “power” from regions to maximize power and reduce power loss for off-design conditions must account for these differences. Pre-conversion power as used herein may thus be quantified as a potential to produce converted power, to account for varying efficiencies. Alternatively, post-conversion power may be quantified in terms of pre-conversion power scaled by an efficiency that may depend on power, uniformity, temperature, etc.

As defined herein, an “optical interaction” is any effect that can change the direction of propagation, intensity, spectrum, or polarization state of light. Optical interactions include but are not limited to refraction, wavelength-selective refraction, diffraction, reflection, partial reflection, wavelength-selective reflection, scattering, polarization, absorption, phase retardation, and conversion.

As defined herein, “pre-conversion combining” refers to the combining of light from separate points to one point, possibly through an optical interaction or sequence of optical interactions. As defined herein, “post-conversion combining” refers to the combining of energy converted from light by a plurality of spatially distinct converters. The combination of converted power within a single converter is herein called “conversion combining”

As used herein “off-design conditions” refer to effects that change an illumination profile from an ideal profile, including mispointing; sag, creep, aging, and damage to a primary collector; distortions from wind loads; collector-to-collector variations; etc.

As used herein an “algorithm” can be a method or procedure. An algorithm may comprise a plurality of other algorithms. An algorithm may comprise a plurality of steps taken serially or in parallel. As used herein, a “step” is a portion of a procedure that is logically distinct from other portions. Some steps may be purely manual, some steps may be purely automated, e.g., via computer control or computation. Some steps may employ explicit calculation. Some steps may employ implicit calculation. Some steps may involve physical testing. Some steps may involve prototyping. Some steps may involve full-scale modeling. Some steps may involve scaled or partial modeling. Steps may be executed once, iterated, looped. Algorithm flow can be conditionally controlled. Loops may be nested. Steps in algorithms may comprise linear and nonlinear optimization techniques. Steps may comprise linear and non-linear solution techniques. Steps may comprise conventional and novel ray-tracing techniques. In some preferred embodiments, steps of an algorithm that require the choice of architectures or compensation strategies may be preferably substantially manual. Steps of an algorithm that require significant calculations, comparisons of large numbers of tactical options, that lend themselves to established numerical optimization and solution techniques, etc. may be preferably substantially automated.

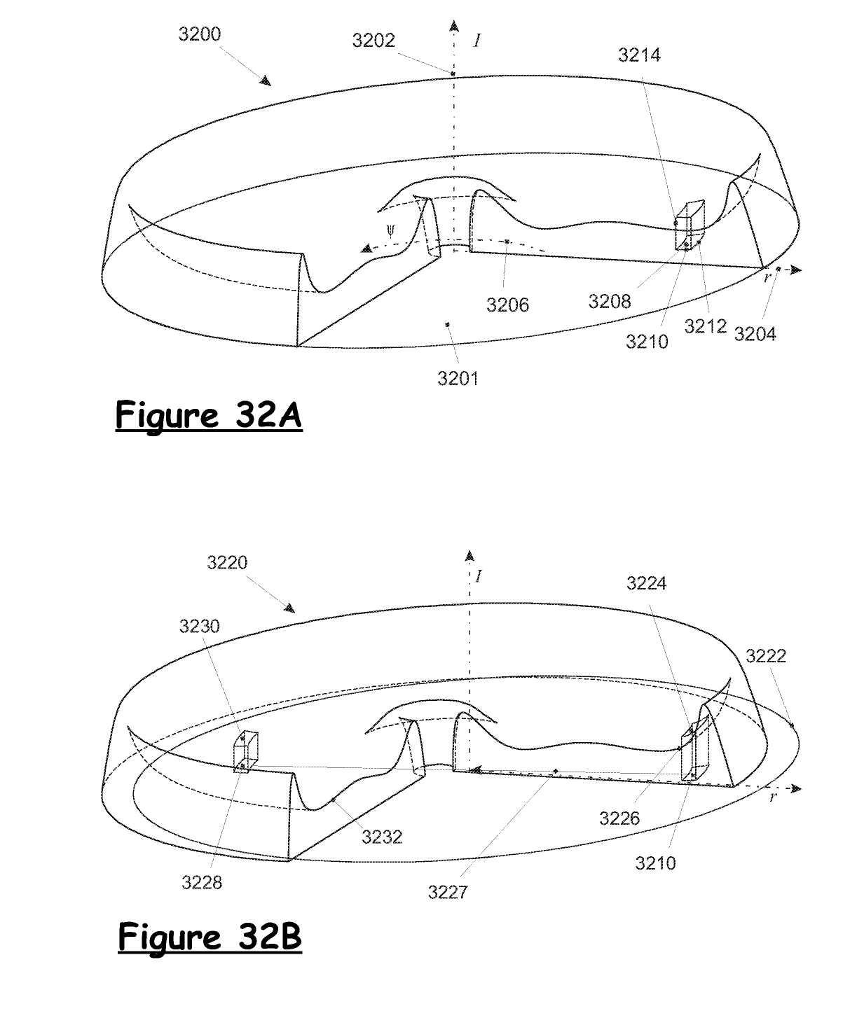

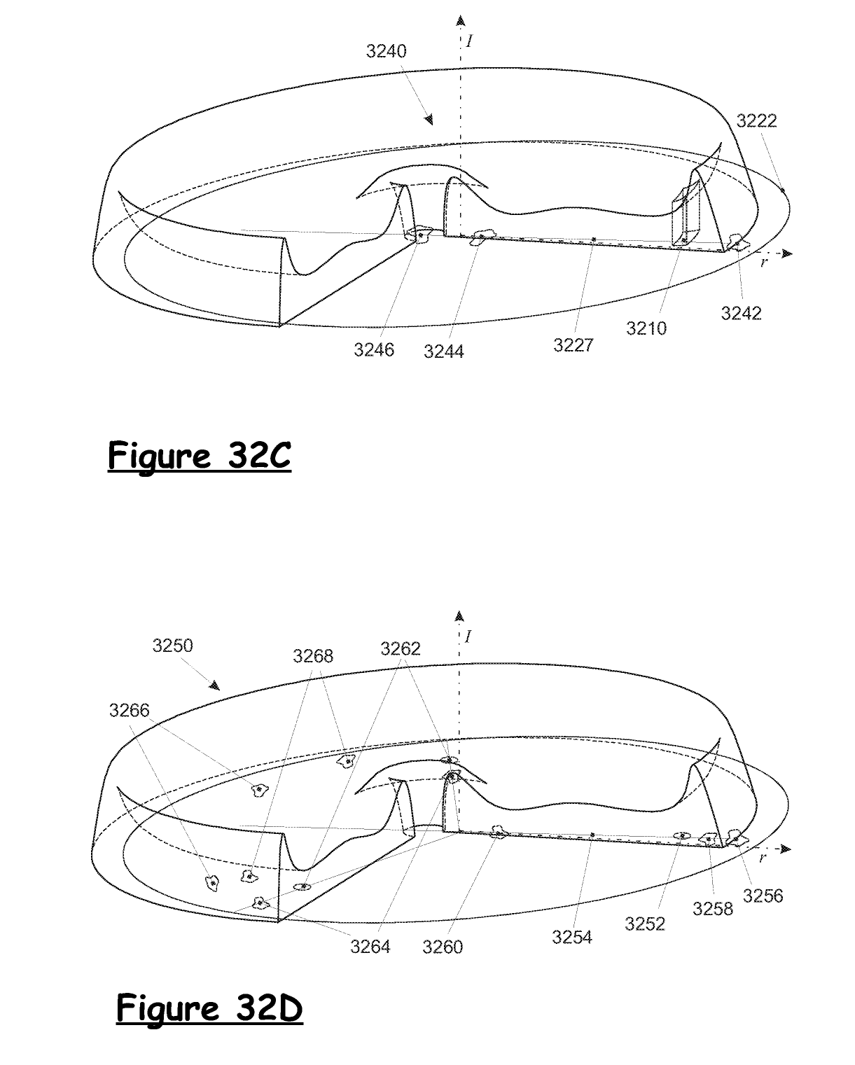

FIG. 32A shows an embodiment of an irradiance profile 3200 on a surface 3201 produced by a primary collector or system of optics. This surface may be flat or curved in an arbitrarily complicated fashion. The surface may represent a physical surface, e.g., a surface of one or more optics, a virtual surface, e.g. a surface that splits space with or without correspondence to physical surfaces. This surface may comprise a set of disjoint, connected, or intersecting surfaces. This surface may be pre-determined, calculated, manually selected, optimized, and subject to iterative changes. Typical locations of this surface include a zone proximate to a focus of a collector. The location of the surface comprises part of its definition and in some embodiments is subject to optimization. Because the incident concentration, illumination profile, and angular sensitivity to mispointing can depend on the choice of location, this optimization can be important for achieving high off-design performance.

The specific definition of the surface can be selected for convenience and performance in the optimization of compensative elements. The surface may be defined by one or more physical surfaces on which irradiance measurements have been taken. The surface may be defined through ray-tracing or simulations. The surface may be modified according to the findings of measurement or simulation so as to produce an illumination profile having desirable characteristics, such as symmetry, reduced illumination gradients, more localized illumination gradients, an illumination pattern that provides for improved compensation as described below, etc. In some embodiments, irradiance is re-measured on an iteration of the surface. In some embodiments, irradiance is re-simulated on an iteration of the surface. While a surface location shown in FIG. 32A can be described using two parameters, e.g., radius and angle or Cartesian parameters, more complex surfaces may be employed in some embodiments. In some such embodiments, such a complex surface may represent the irradiance in different discrete regions of space. In some embodiments, the surface may represent a surface of an optic, e.g., a secondary optic's front, back, or interior surface, a surface on or within a tertiary optic, etc. Some complex surfaces represent physical shapes that are multiple valued, such as layered or negative-draft surfaces.

The axis 3202 represents the incident power per unit area, I. Axis 3204 represents the distance r along the surface 3201 in the radial direction. The arrow 3206 represents the angular ordinate ψ. This embodiment shows an illumination profile having substantial radial symmetry, however the following discussion applies equally to embodiments having other symmetries or distribution and is not intended to be limiting to a symmetry class.

In the design of a compensative receiver, it is useful to divide a surface conceptually or physically into discrete contiguous regions according to where the illumination power is converted from light energy. These regions can be predetermined, set manually, fixed, variable during operation, variable during optimization, variable between iterations. Regions can exist for some off-design cases and not others, e.g., light may miss a region or the angle of light may exceed a threshold required for a region to exist, such as a TIR condition in one illumination state and not another. Region boundaries can be tied to physical structures on an optical surface, for example the boundaries of lenslets having relatively abrupt slope changes at the boundaries, or functional structures, such as a region of a lens that directs light toward a boundary of a converter or toward an abrupt transition such as a notch between adjacent TIR concentrators or other boundary between light following one path or a substantially different path. Thus, regions may be defined by optical function.

Regions may alternatively be defined by mathematical structures, such as separatrices.

Regions may be used algorithmically as an input: a given element from which other elements are derived or optimized. Alternatively, regions may be used algorithmically as an output: the result of an optimization or calculation. Some algorithms may employ regions both as inputs and outputs in different stages of calculation or optimization. In some algorithms, the region boundaries are prescribed. In some algorithms, the region count is prescribed. In some algorithms, the maximum region count is prescribed. In some algorithms, the count of coupled regions is prescribed. In some algorithms, the maximum count of coupled regions is prescribed. In other algorithms, the count of regions or coupled regions is determined through optimization or calculation. In some algorithms, the location of a region is specified or calculated. In some algorithms, the area of a region is specified or calculated. In some algorithms, the power incident on a region is specified. In some algorithms, the change in power at an off-design parameter is specified or calculated. In some algorithms, the change in power is specified or calculated to vary substantially in opposition to that of another region for one or a plurality of off-design conditions. In some algorithms, the sum of changes in power irradiating a plurality of regions is specified or calculated to vary less than a threshold value with one or a plurality of off-design conditions. In some algorithms, variations with off-design condition are parameterized and expressed substantially as a series approximation that is, in some cases, discretely calculated and in others analytical. In some algorithms, variations are expressed as terms of a Taylor series. Some algorithms set limits on coefficients of terms in a series expansion. Some algorithms automatically increment or decrement the count or other parameters of coupled regions. Some algorithms use results of region optimization to adjust the definition of the surface. Some algorithms are different for different parts of the surface.

The completeness of a description of a receiver may change over the course of an algorithm. For example, early steps in the algorithm may seek to partition a surface into roughly compensative areas having substantially uniform target total power for each coupled region. In other embodiments, the target total power for coupled regions may be selected from a plurality of values that may be prescribed or may be refined or obtained iteratively.

In some algorithms, this partitioning may ignore or pay cursory attention to optical limitations such as TIR conditions, effects of finite-thickness optics, etc. In some algorithms, these steps may be manual. In some algorithms, a cursory partition is then simulated with better accuracy to check for physical problems, such as manufacturing issues like draft angle, exceeding TIR limits, excessive Fresnel losses etc. In some algorithms, this cursory partition is refined to achieve improved compensation. In some embodiments, this refinement step is followed by an evaluation of the suitability of the initial choices, such as count of coupled regions; distribution of coupled regions; total region count; whether power is coupled optically, electrically, or a combination; etc. In some embodiments, this refinement step is iterated with new partition choices. In some embodiments, a refinement step is followed by an assessment of the suitability of the chosen surface and possibly the selection of a new surface.

Some algorithms may prompt the development of a three-dimensional surface target, possibly by rapid-prototyping techniques well known in the art and possibly by the use of a re-configurable target, including a target that can be reconfigured under computer control. This target may be placed in an actual concentrator or model concentrator to obtain improved irradiance measurements on an iterated surface. The decision to use physical measurements over ray traces may be prompted by the need for increased accuracy, speed in developing a large set of off-design-condition data, and the desire for an independent cross-check of the accuracy of the collector model. Conversely, some algorithms may prompt the development of accurate ray-traced irradiance simulations on a new surface.

In some embodiments, after a favorable partitioning, a detailed simulation may be employed to refine region boundaries and develop the physical structure of the optics. Generally, a solution is non-unique, so each optical partition may be further optimized for improved manufacturability, such as larger draft angles, maintaining sufficient web thickness, steering light away from regions that are filleted or radiused to facilitate molding, increase the deviation of angles from their TIR limits, etc. In addition, each partition design can be refined to minimize Fresnel losses, produce a substantially uniform illumination on a converter, etc.

In some embodiments, the algorithm attempts to couple light to an element of a finite set of converter geometries. In some embodiments, this set contains one converter geometry. In some embodiments, the algorithm may change the orientation of a converter as part of its optimization. In some embodiments, the geometry of at least one element may be changed manually or automatically as part of the algorithm. In some embodiments, additional converter geometries may be prompted or added automatically if required. The addition of a new converter geometry may be deprecated or negatively viewed by an algorithm because this may increase component costs over that of a single component. However, benefits of the optimization of shape may offset other costs by reducing the required amount of converter material and improving the overall optimization of the receiver. In some embodiments, the shape and size of conversion elements vary. Such embodiments may provide for a reduction in cost of free-form converters or a large plurality of converter geometries by advanced techniques, such as laser dicing.

At the end of these optimizations, the boundaries of the regions may need to be re-adjusted. The data from the detailed simulation, e.g., average Fresnel losses across a surface, may be used in this refinement as an improved parameter to a lower-fidelity optical model, such that region refinement iterations can be performed relatively quickly, but with improved accuracy by the use of simplified data, e.g., “effective parameters,” from a high-fidelity model.

Some embodiments may provide for a primary optic having adjustable characteristics. For example, an inflated concentrator may adjust its profile by changing its inflated volume. Some embodiments provide for receivers that can change position. Some embodiments provide for elements whose relative position or shape may change automatically, e.g., under the influence of light or thermal energy, under passive driving, e.g., inertia or gravity, or actively, etc. Some embodiments of algorithms further incorporate these non-stationary elements into their optimization.

In some embodiments, an algorithm may require a manual choice or automatically choose to perform post-conversion coupling between regions if a valid or suitable solution for optical coupling is not found.

In some embodiments, an algorithm may choose or prompt to merge proximate regions having favorable characteristics, for example, whose sum power better matches a target power, whose merging improves or changes compensation modestly, etc. Such merging may be favorable for reducing the complexity or number of converters.

Conversely an algorithm may choose or prompt to split regions having favorable characteristics, such as the ability to series connect converter elements of the split regions efficiently and without a substantial loss in total converted power over the un-split region. One reason to perform this split may be to achieve a larger string voltage or a smaller string current than a single region produces.

Some algorithms start with a relatively small number of regions and progressively split regions to obtain a target receiver characteristic, such as output voltage. Conversely, some algorithms start with a relatively large number of regions and progressively merge regions to obtain a target receiver characteristic, such as converter count.

Some algorithms incorporate data in raster format, e.g., irradiance bitmaps. Some algorithms delineate regions in a raster format at least at one step. Some algorithms delineate regions in a vector form at least at one step. In at least one step, some algorithms delineate regions according to a mathematical function, e.g., a parameterized curve. In at least one step, some algorithms delineate regions according to a mathematical generating function, such as a level-set method.

The converters in some embodiments are photovoltaic cells. Some cells may be series connected in a string that is paralleled with at least one other string at the negative-most and positive-most terminal of the string.

In some such embodiments, substrings or individual die may be paralleled with their counterparts in another string using redundant conductors. In some embodiments, these conductors pass significantly less current than that of the series connected strings. In some embodiments, these conductors ideally pass only imbalance current arising, for example, from off-design operation or imperfectly compensated operation. Such connections may have the advantage of requiring substantially smaller conductors than would otherwise be necessary if the strings were not separately series connected.

In some embodiments, the algorithm may prompt or choose to incorporate bypass diodes or switches to optimize receiver performance. Bypass diodes or switches may be incorporated on the single-cell, substring, or string basis. Some embodiments reduce performance loss by the use of a redundant bypass diode or switch that shunts a plurality of bypass diodes or switches, thereby reducing the combined voltage drops that would otherwise accumulate by series connection.

Because of lengthy computational, measurement, and prototyping times and the large number of optimization parameters, a significant figure of merit of an algorithm may be the time to a good solution rather than the performance of a fully optimized receiver. Conversely, the economic benefit of a fully optimized receiver may justify extraordinarily time intensive optimizations. In some embodiments, parallel processing may be employed to reduce solution time. In some embodiments, the solution time is reduced by judicious ordering of steps and grouping of optimization parameters within steps. In some embodiments, architecture and “strategic” level choices are made substantially manually, possibly with comparatively fast helper tools, e.g., irradiance quantifiers, design-rule checkers, etc. In some embodiments, “tactical” level choices and optimizations are made substantially automatically, possibly with manual intervention when numerical algorithms fail to converge. In some embodiments, analyses and simulations start out relatively crude and become more refined and accurate as a design converges. In some embodiments, the results of a detailed simulation are extrapolated or interpolated using perturbation approaches. For example, a detailed irradiance measurement or simulation on a surface may be transformed to approximate a mispointed irradiance pattern by a simple coordinate translation or a more complicated mapping translation, for example, obtained by an asymptotic or perturbation analysis of such effects.

As used herein “optical losses” comprise absorption losses, scattering losses, specular reflection losses, diffuse reflection losses, Fresnel losses, etc.

One preferred embodiment of a ray tracing algorithm to delineate and quantify power accurately on regions comprises at least one of the following steps:

1. Use a prescribed angular mispointing and parametric primary-optic surface description to define the angles or range of angles at which light from a point source or extended source respectively leaves the primary-optic surface.
2. Calculate shading boundaries by numerically tracing a plurality of rays toward the sun:
2.1. Launch rays from the primary optic surface toward the sun across a grid that is sufficiently dense to ensure that each significant shadowing element, e.g., receiver, mounting apparatus, structure, etc., intercepts at least one ray. If a ray hits a shadowing element, do not trace it further.
2.2. Identify the boundary between a ray that misses a shadowing element and a ray that hits a shadowing element.
2.3. Iteratively refine a point on the boundary, e.g., by the use of a bisection or faster algorithm that progressively narrows the distance between the last “hit” and last “missed” ray until the difference is insignificant. Alternatively, it is possible to speed this process by analytically extending elements and having them report one or more “impact parameters” of a ray, e.g., continuously variable numbers that take known values when the ray precisely hits an extremum of an element. The impact parameters may then be used in a fast-converging numerical solver, e.g., Brents method, Newton's method, the Secant method, or other techniques well known in the art.
2.4. Trace and record the outline of the boundary from this point and record the locus of starting positions on the primary optic, e.g., as a polygon, spline, or other general shape by a repeated process of stepping and refinement until the shadow region is fully defined. Alternatively, repeat the procedure 2.3 until an adequate description of a shadow region boundary is obtained
2.5. Repeat 2.1-2.4 or 2.2-2.4 for all shadow region boundaries
3. Identify and quantify regions
3.1. Create a second group of rays. The starting point of these rays may be a uniform grid, random grid, or non-uniform grid on a primary optic surface. The spacing between ray start points should be sufficiently small that rays incide on substantially all significant regions of the subsequent optics, e.g., the optical power that falls on a region of the primary between rays should be sufficiently small to be negligible. For computational efficiency, preferably exclude rays that lie in a shadow region.
3.2. Numerically launch rays from this group toward the receiver according to the angles rays would exit the primary surface.
3.3. Trace rays until they reach a converter or are lost; recording the path each ray takes to its conclusion. In some preferred embodiments, each primitive surface of an element has a unique number. Changes in a path may be identified by forming a path checksum by performing an operation, e.g., xor, add, subtract, etc. of a saved path variable with the identifier of each surface that intercepts a ray.
3.4. Identify the boundary between a ray that takes one path and a ray that takes another path.
3.5. Refine a point on the boundary using a technique as outlined in step 2.3.
3.6. Construct the locus of starting points that incide on a region border as outlined in step 2.4.
3.7. Repeat 3.2-3.6 or 3.4-3.6 for all found regions.
3.8. Exclude from the loci any points that are shadowed. This can alternatively be done during step 3.6.
4. Calculate the power in each region. For each region:
4.1. Calculate the starting power that would incide within the locus of points on the primary by reverse ray-tracing or analytically calculating the area of the locus projected normal to the source, e.g., sun or point source.
4.2. Simulate, look up, or approximate optical losses in the path to the primary optic. For improved accuracy, some embodiments may separately treat losses for different polarizations or wavelengths.
4.3. Simulate optical losses from the primary.
4.4. Simulate or look up optical losses in the forward ray path to a converter.
4.5. Scale the total power by the product of the losses.

This algorithm and variants may provide speed advantages over conventional ray tracing calculations of irradiance. Uncertainty of a conventional irradiance calculation scales as the inverse square root of the number of traced rays whereas the uncertainty of this irradiance calculation scale as the inverse of the number of traced rays, which is a significant improvement. This novel algorithm can rely on a comparatively sparse calculation of boundaries rather than the conventional dense calculation of ray density on surfaces. The algorithm also can avoid calculating the point of interception with a primary optic, facilitating the efficient analysis of primary optics having complicated shapes. In addition to considerable speed enhancements, the algorithm natively performs partitioning into regions, which may be useful in other aspects of the optimization algorithm.

This conversion may take place directly, for example by filling region 3210 with a converter, after further optical processing, for example, a sequence containing refractions, diffractions, reflections, total internal reflections, etc. on the way to a converter element. The power per unit area that lands on a region 3208 can be integrated or summed to obtain a total power incident on the region, equal to the volume of the element 3214. The boundaries of the region can in some embodiments be defined by a radial extent 3210 and an angular extent 3212, triangle, rectangle, hexagon, other polygon, or more general boundary.

FIG. 32B shows an illumination pattern 3220 corresponding to a mispointed or otherwise off-design condition. The illumination profile resulting from a mispointed or otherwise off-design condition is shifted a distance from its on-design position, 3222. As a result of this shift, the integrated or summed power 3224 on region 3210 increases because the region receives more irradiance than in FIG. 32A, lying on the zone 3226 on the irradiance curve. Such an increase in power may be unfavorable if the performance of a receiver depends on carefully controlling the relative incident power on converters.

In some embodiments the effect of off-design intensity changes is mitigated by combining the power that falls on a plurality of regions whose power variations under off-design conditions substantially offset each-other over a range of off-design conditions. In some embodiments, this power combining occurs in full or part before the light power reaches a converter, called optical compensation. In some embodiments, this power combining occurs in full or part after the light power reaches a converter, called post-conversion compensation. If the conversion element produces electricity, this post-conversion power combining is called electrical compensation. FIG. 5B shows an example of optical combination with element 570 and 580 combining light from distinct regions onto converter 552.

If the irradiance profile 3200 has substantial mirror symmetry in the direction 3227, the power increase on surface 3210 can be compensated in part by combining that power with that from a symmetrically disposed region 3228, whose integrated power 3230 is reduced over its on-design value because the region falls under a zone 3232 of lower irradiance. Such a compensation scheme may provide perfect compensation for infinitesimal displacements of the illumination profile, since the paired regions have exactly opposing slopes to the irradiance curve. However, finite displacements may generally not be well compensated because of higher-order derivatives of the illumination profile, e.g., because the illumination profile is sharply curved, the increase in 3224 is greater than the decrease in 3230 and perfect compensation is not achieved.

In some preferred embodiments, elements at opposite points on the inner or outer periphery of a receiver are combined. In some embodiments, this corresponds to adding converters that are partially illuminated or not illuminated for some off-design conditions, and possibly even the ideal, on-design condition.

Some embodiments combine power from two, non-symmetrically disposed regions of a surface. FIG. 32C shows three candidate locations 3240 for compensating cells whose integrated irradiance varies oppositely to that of 3210. Location 3242 may be advantageous in part because its proximity may facilitate pre-conversion combining. Both locations 3244 and 3246 may require post-conversion combining. The relative area and shape of the regions may be adjusted to null or minimize the combined power change for one or a plurality of off-design conditions. The compensating locations shown in FIG. 32C lie along a diameter of the profile. In some embodiments, for example, when the pointing or other error is disposed symmetrically, substantially diametral arrangements may have advantages. With other distributions of illumination and other distributions of off-design conditions, pairing of two elements that lie on different diameters may be advantageous.

Some embodiments further improve power compensation by combing power, either pre-conversion or post-conversion, from three regions. FIG. 32D shows possible compensating arrangements 3250 for a region 3252. These arrangements may comprise regions that lie substantially along a diameter 3254. For example power from 3252 may be combined with that from 3260 and 3256 or 3258. Alternatively power from 3252 may be combined with that from 3256 and 3258. The proximity of these regions may facilitate pre-conversion combining of the energy.

Alternatively, non-diametral compensating elements may be disposed as a rotationally symmetric group 3252 and 3262. Alternatively a trio of non-diametral compensating elements may be disposed substantially at 120° from each other but with radial offsets (3264). Alternatively, non-diametral compensating elements (3266) may be disposed symmetrically about the diameter 3254. Alternatively, non-diametral elements may be disposed more generally (3268).

Some embodiments improve power compensation by combining power, either pre-conversion or post-conversion, from four regions. FIG. 32E shows some embodiments of placements 3270 of elements that compensate power changes on region 3272. In some embodiments, one of the compensating elements is oppositely disposed (3274). In some embodiments four elements are co-diametral (along 3276), e.g., 3272, 3274, 3280, and 3282 or 3272, 3274, 3284, and 3286. In some embodiments, four elements are diametral, but not otherwise disposed symmetrically.

In some embodiments, some compensating regions are disposed along the diameter 3277, at 90° from diameter 3276, e.g., rotationally symmetrically, 3272, 3274, 3287. In other embodiments, compensating regions along 3277 are symmetrically disposed about 3276, 3294 and 3290.

In other embodiments regions are disposed symmetrically about 3276, e.g., 3272, 3274 and 3288.

In other embodiments regions are disposed symmetrically about another diameter, e.g., 3292 and 3293.

In other embodiments, regions are disposed without concern for symmetry.

Other embodiments may compensate a region with an arbitrary number of regions, disposed symmetrically about an axis, diametrically, symmetrically with respect to a diameter, and arbitrarily.

Some preferred embodiments are optimized for best power matching at finite displacements, angular tilts, or other such off-design condition. Optimizing for finite errors may improve the range of compensation better than designs, having the same number of combined, compensating regions that are optimized for infinitesimal or small errors.

The power of a combined region can be adjusted by adjusting the size of each region substantially proportionally. The changes in total power for off-design conditions can be reduced by changing the relative size of each region. Greater numbers of regions involved in compensating each other have more degrees of freedom to minimize total power changes for a plurality of off-design conditions.

It is sometimes necessary to compensate for non-uniformity in the lobe by redistributing the irradiance incident on the secondary optic across cells optically, by optical interaction before electrical compensation. Such optical compensation can negate the need for electrical compensation or enable electrical compensation. Examples of optical interactions are partial internal reflection sometimes called frustrated total internal reflection, total internal reflection (TIR), refraction, scattering also known as diffusion, diffraction, and the holographic equivalents of these. For example, a hologram of a lens is itself a lens and will substantially redirect light similar to a lens. In another example, a holographic diffuser can diffuse light through a specific set of angles compared to a simple diffuser that might use surface roughness to diffuse light through a continuous range of angles.

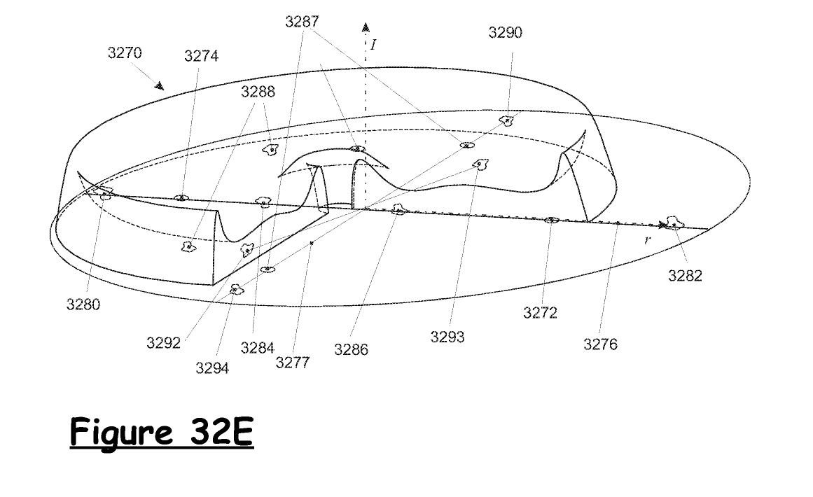

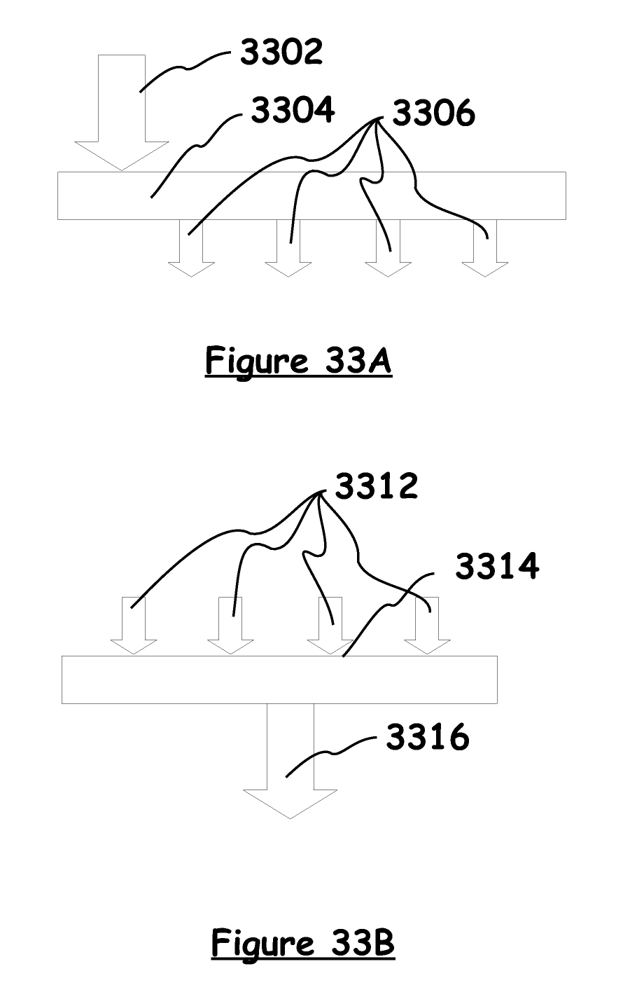

Redistribution of the energy is generally done one of two ways. In FIG. 33A, one region of irradiance 3302 is distributed among two or more regions 3306 by interaction with an optical system 3304. Due to conservation, the total energy output to regions 3306 sum to equal the input energy on region 3302 less any losses in the system. In the other way as illustrated in FIG. 33B, two or more regions of irradiance 3312 are combined by interaction with optical system 3314 into one region of irradiance 3316. By conservation, the total input energy 3312 is delivered by the optical system 3314 to region 3316 less any losses in the system.

An example of when this technique is used is when the lobe has a relatively intense perimeter as shown in FIG. 11 and again in FIG. 32A. Rather than sizing the cells where the lobe is nominally incident proportional to the intensity, it may be desirable to redistribute the energy in this part of the lobe across several cells. This later technique eases the task of electrical compensation during tracking errors and is called optical compensation.

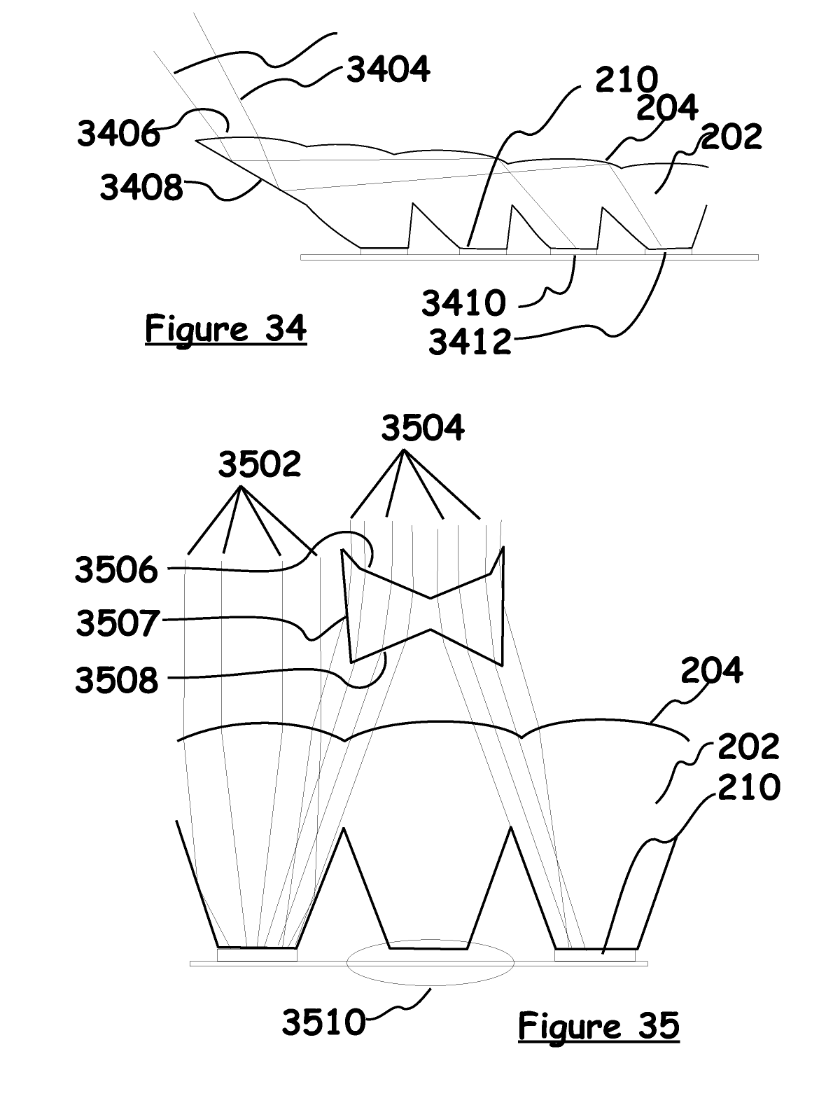

An example of optical compensation is shown in FIG. 34. Rays 3402 and 3404 are of relatively high intensity and rather than being directed to a single energy conversion cell (“cell”) or an adjacent cell are distributed across several cells 210. Optical interaction at the periphery of the secondary optic 202 directs light rays 3402 and 3404 across the secondary optic until they are distributed to distal cells 3410 and 3412. In this embodiment, the optical interaction is by refraction at first surface 3406 and total internal reflection at second surface 3408. Subsequent optical interactions include TIR at features of first surface. In this embodiment, the TIR features for internal rays 3406 and 3408 are also refractive features for rays incident on first surface 204 from the primary concentrator (not shown).

In an alternative embodiment, the lobe has a non-uniform irradiance due to the shadow of a structural element. When the shadow falls on a row of energy conversion cells such as photovoltaic cells the cells produce a lower voltage more or less proportional to the reduced irradiance, reducing the efficiency of the electrical circuit of which the cells area a part. In a preferred embodiment, the cells are eliminated and the radiation that would have been incident on the cells is instead redistributed among the remaining cells by optical interaction. In FIG. 35, rays 3502 are of normal intensity while rays 3504 are of lesser intensity due to being in the shadow of a structural element that is aligned with a row of cells in the receiver. Three such rows are seen in cross-section if FIG. 35. Rather than place an energy conversion cell 210 at the location indicated by 3510, this position is left unpopulated and the diminished irradiance that would normally fall on the cell 210 at location 3510 is instead diverted and in this case split between the two adjacent cells by optical interaction. In a particular embodiment, the optical interaction is by means of a separate optical element 3507 deployed above the shadowed row. Rays of normal intensity 3502 are incident on secondary optic 202 and refracted and reflected until they are incident on one of the cells 210. Rays of less intensity 3504 are incident on ray splitter 3507 whereby various optical interactions split the energy between the two adjacent cells 210. In this case, the optical interaction is by a linear axicon and rays 3504 are first refracted by surface 3506 and caused to diverge and are caused to further diverge by refraction at surface 3508.

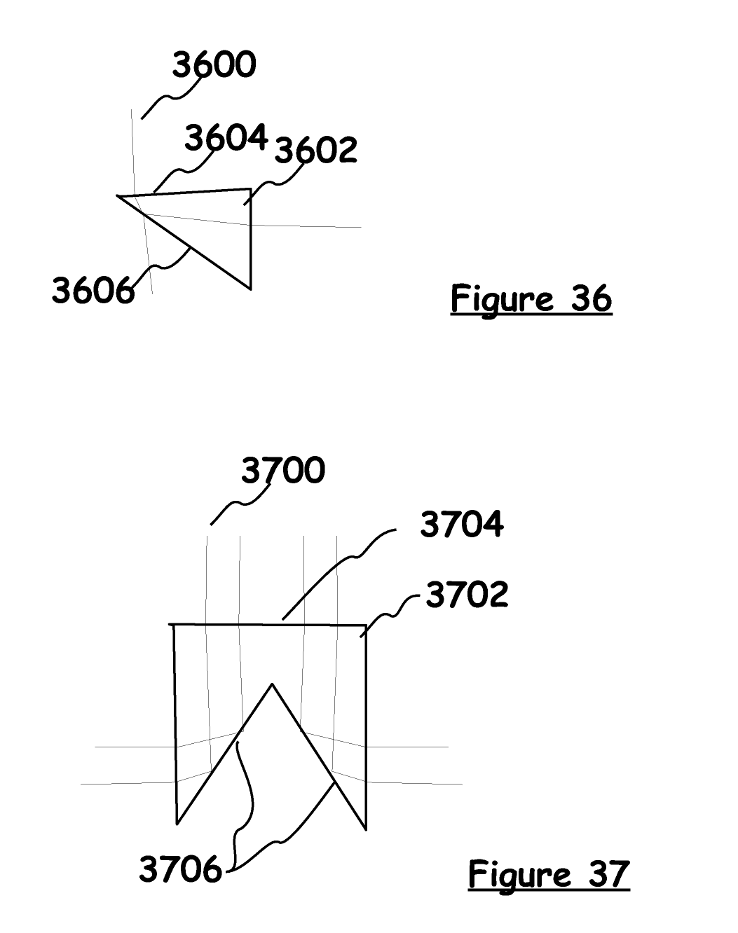

FIGS. 36 and 37 show optical interactions including beam splitting by frustrated TIR (FIG. 35) and by reflection from a roof prism. Here the roof prism is a negative prism (a prism “made of air”) and the reflection is by TIR.

In the first case, incident light 3600 enters first surface 3604 of optical element 3602 and encounters second surface 3606. The angle of incidence between ray 3600 and surface 3606 does not meet the criteria for TIR so part of the ray is reflected and the other ray is transmitted. In this way energy can be split between the incoming ray and two exiting rays.

In the second case, incident light 3700 enters first surface 3704 of optical element 3702. Rays 3700 then encounter one of two facets of second surface 3706 and are redirected by TIR, with part of the energy exiting in one direction and the other part exiting the other direction. If the angle between the rays 3700 and second surface 3706 do not meet the criteria for TIR, then some will be transmitted and some will reflected resulting in the energy being distributed in 3 different directions.

These examples illustrate how incoming energy may be either combined from different regions into one region or distributed from one region to many. Other techniques for combining energy such as diffraction, diffusion and holographic techniques may also be used. While other techniques known in the art to combine energy such as metallic beam-splitting coatings and “polka-dot beam-splitters” may be used, devices using metallic fully or partially reflective coatings tend to absorb a small fraction of the incident energy but sufficient enough to greatly shorten useful life. In contrast, reflections based on TIR and partial reflections based on frustrated TIR and dielectric coatings, both broad spectrum and wavelength-selecting, tend to absorb sufficiently little energy so as to have a useful service life.

Optical compensation may involve, in part, partitioning or splitting light. Light can be split by the use of spatially inhomogeneous geometries, surfaces, and material properties. For example, a refractive surface having a substantially abrupt slope change or thickness change can direct light from one side of the change, possibly following other optical interactions, to one converter, and light from the other side of the change, possible following other optical interactions to another converter. A gradual or abrupt change in slope may alternatively transition between TIR and transmission, directing light from one side of the transition and the other ultimately to separate converters. Alternatively, the propagation of light can be partitioned by geometrical discontinuities, such as an edge of a mirror or refractive surface or a cut in a refractive surface. In some embodiments, light can be split to follow separate paths by a beam splitter according to a variety of techniques that are well known in the art.

Primitive splitters according to embodiments of the present invention may be constructed by compositing two optical interactions, possibly the same type and possibly different types having different effects or compositing an optical interaction with no interaction.

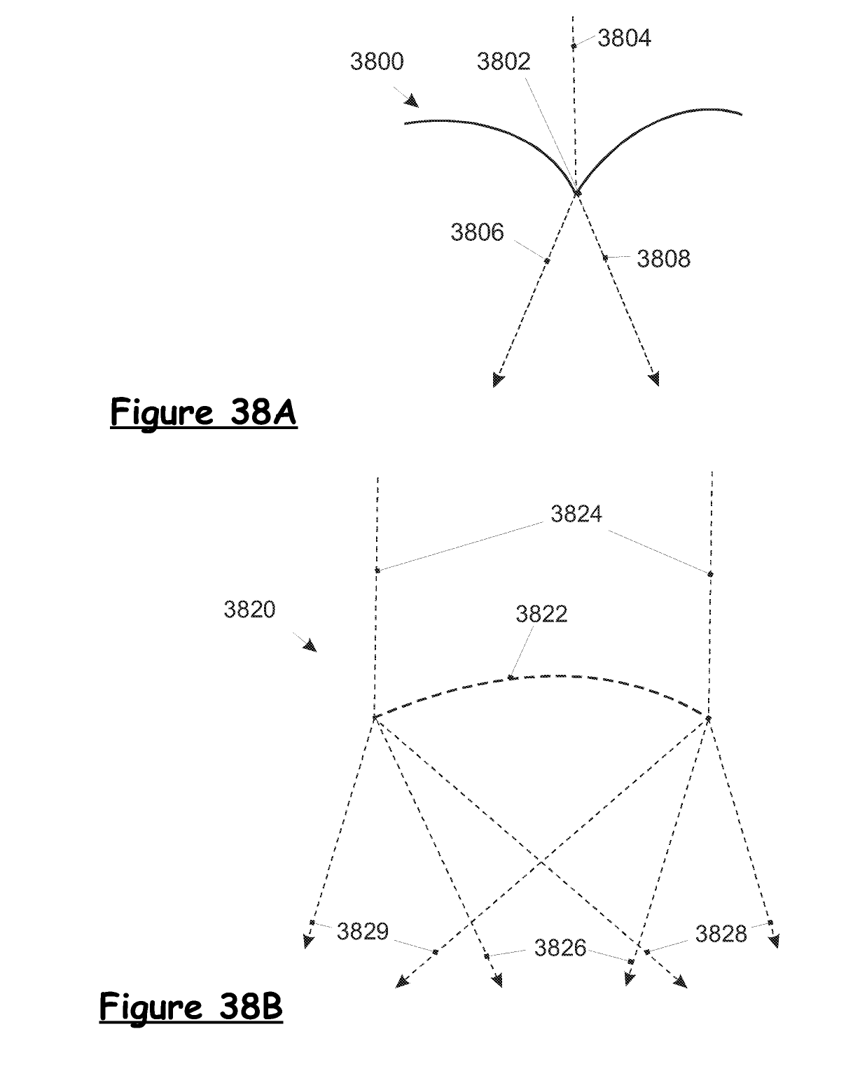

For example, FIG. 38A shows an embodiment of a primitive splitter (3800) based on two refractions. The splitters surface contains an abrupt slope change 3802 such that rays to the left of 3804 propagate to the left of 3806 and right to the right propagate to the right of 3808. Alternatively the same refractive spitting effect can be achieved with an abrupt thickness change.

FIG. 38B shows an alternate embodiment of a primitive splitter. Primitive splitter 3820 is a diffractive, Fresnel, or holographic surface 3822 that may also perform refraction to split incoming ray bundle 3824 into a plurality of ray bundles, 3826, 3828, and 3829. Bundle 3826 may result from zero-order diffraction.

Favorable embodiments of splitters may not excessively scatter or absorb light and may not interfere with the operation of other optical elements. Some favorable embodiments may perform multiple simultaneous optical tasks, e.g., splitting and focusing, splitting multiply, splitting and directing light, splitting and combining, etc.

Optical compensation may involve, in part, combining light from separate regions onto a converter. Pre-conversion combining can be achieved at a point by multiplexing light rays from different directions. For some converters, this range of directions may be approximately 4π steradians. For many converters, this range of directions is limited to about 2π steradians. For many converters the range of efficient collection angles is less than the limit, since rays incident on a converter at grazing angles may not be converted efficiently. When the angular range of the converter at a point is filled with incident light, no further combining can be performed without affecting light from other directions, for example, splitting a portion of light away from the point of the converter.

Light can be combined from separate regions by interacting light with spatially inhomogeneous geometries, surfaces, and material properties. Combiners can be created by compositing two optical interactions having different effects or compositing an optical interaction with no interaction.

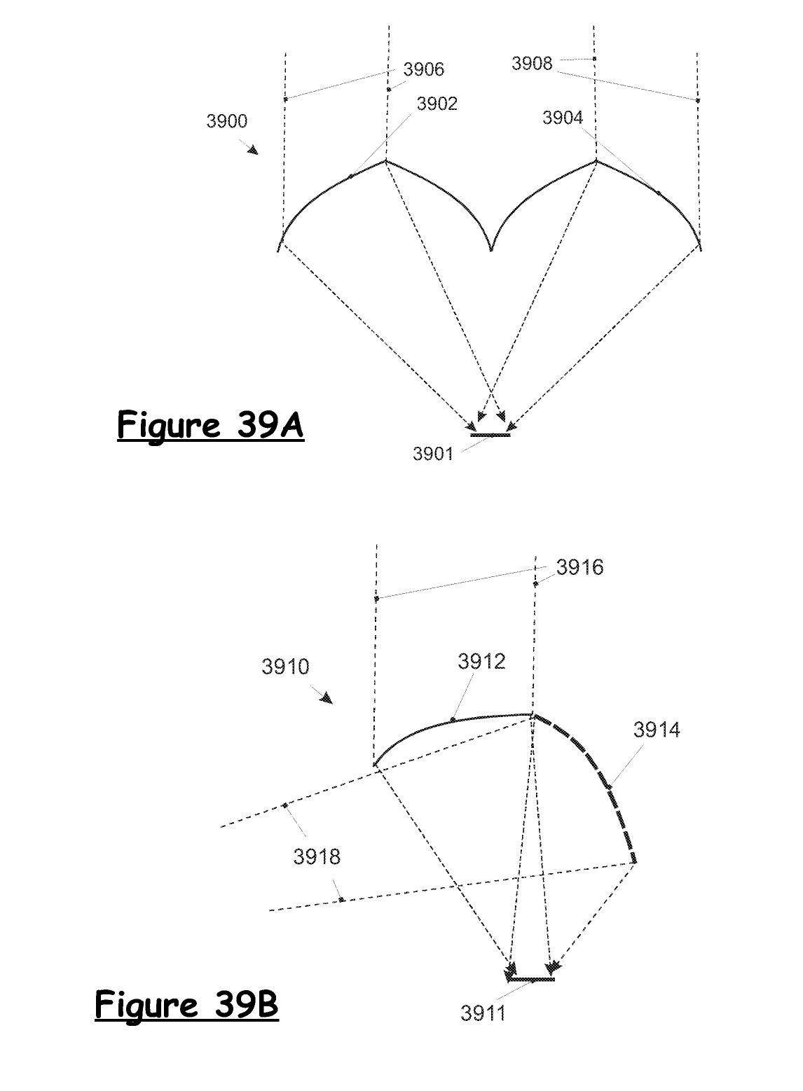

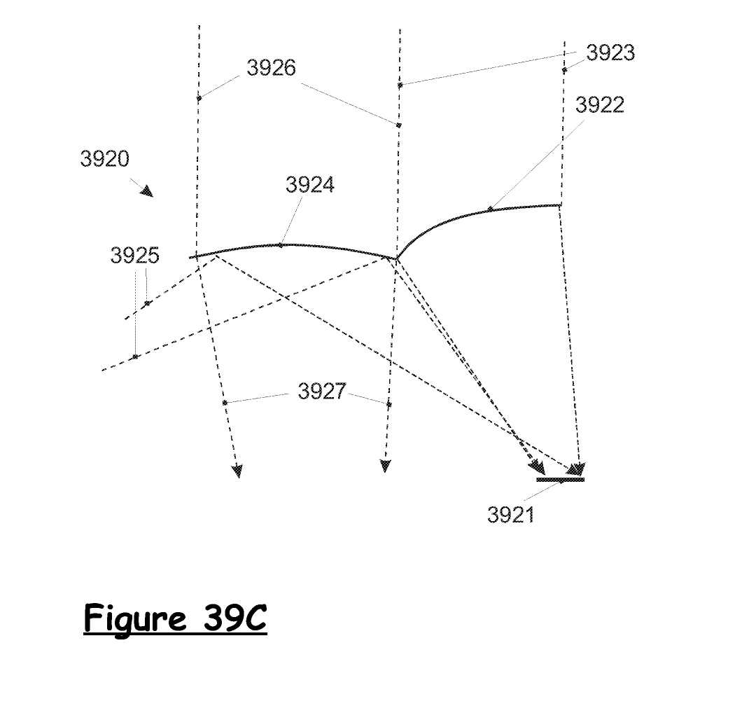

For example, FIG. 39A shows a fully refractive combiner primitive 3900 having surfaces 3902 and 3904 which respectively redirect distinct ray bundles bounded by 3906 and 3908 to a common converter 3901.

FIG. 39B shows another embodiment of a combiner according to the present invention. Primitive combiner 3910 composites a refractive element 3912 and reflective element 3914 which respectively direct ray bundles 3916 and 3918 to converter 3911.

In FIG. 39C, primitive combiner 3920 comprises surfaces 3922 and 3924 which respectively refract ray bundle 3923 and reflect via TIR ray bundle 3925 to converter 3921. In some embodiments, surface 3924 is design to split ray bundle 3926 from 3923 and refract it into bundle 3927.

Preferred embodiments of combiners may not excessively scatter or absorb light and may not interfere with the operation of other elements. Some favorable embodiments may perform multiple simultaneous optical tasks, e.g., combining and focusing, combining multiply, combining and directing light, combining and splitting, etc.

Some embodiments of the present invention comprise a composition of a plurality of splitter and combiner primitives to perform pre-conversion compensation, for example, as shown in the embodiments in FIGS. 1-5, 10, 21-27.

Passively Compensative Electrical Interconnections

Many material-efficient concentrators produce an illumination pattern that is substantially radially symmetrical. This discussion explicitly shows embodiments of receivers that employ photovoltaic converters having compensation schemes based on a substantially radially symmetrical cell pattern. The same compensation techniques apply without substantive modification to receivers having different geometries (e.g., rectilinear or hexagonal arrays, etc.) and the focus on radially symmetric designs is not intended to be limiting.

In some embodiments of the present invention, the goal of electrical compensation is to provide the largest possible acceptance angle and least sensitivity to focus and primary concentrator shape errors, while maintaining peak power at the highest voltage for a given number of interconnected die. The highest peak-power voltage corresponds to the lowest peak-power current, requiring less material or producing less loss in electrical interconnects. Having a large number of die increases the assembly cost of the solar module, and may generally increase kerf loss effects and reduce reliability.

In some embodiments, the cells on the receiver are shaped like that shown in FIG. 6. The relatively high aspect ratio of the cell (˜5) reflects the relative ease of concentrating in one direction, in which the angular extent of rays is relatively restricted, allowing a large amount of secondary concentration, and another, where the angular extent is relatively broad, allowing a lesser amount of secondary concentration.

In the case of a radially symmetric concentrator, incoming rays generally span a greater angular range in the radial direction than in the circumferential direction, particular for “fast” or low f/number concentrators. In contrast, an angular spread of incoming rays in the circumferential direction may be produced by shape errors in the primary concentrator or pointing errors. A cell aspect ratio between about 1 and 20 is favorable, with some embodiments having a range between about 1.5 and 10.

At high aspect ratios, increased kerf losses may be problematic, particularly for physically small (e.g., millimeter scale) die. An advantage of high aspect ratios is an improvement in grid efficiency, if the cells have front metallization. As shown in FIG. 6, comb-like structure comprising metal fingers 620 joined at a metal bus bar 630 having wire or ribbon bond pads 640 may be desirable.

Metallization may employ a variety of bulk metals, e.g., aluminum for its low cost and moderately good conductance, gold for its good conductance and inertness. Silver or copper bulk metallization is also possible, but less standard in industry. A variety of metals may be employed in thin films to enhance adhesion, lower contact resistance, reduce inter-metallic diffusion, etc. Alternatively, cells could employ backside metallization.

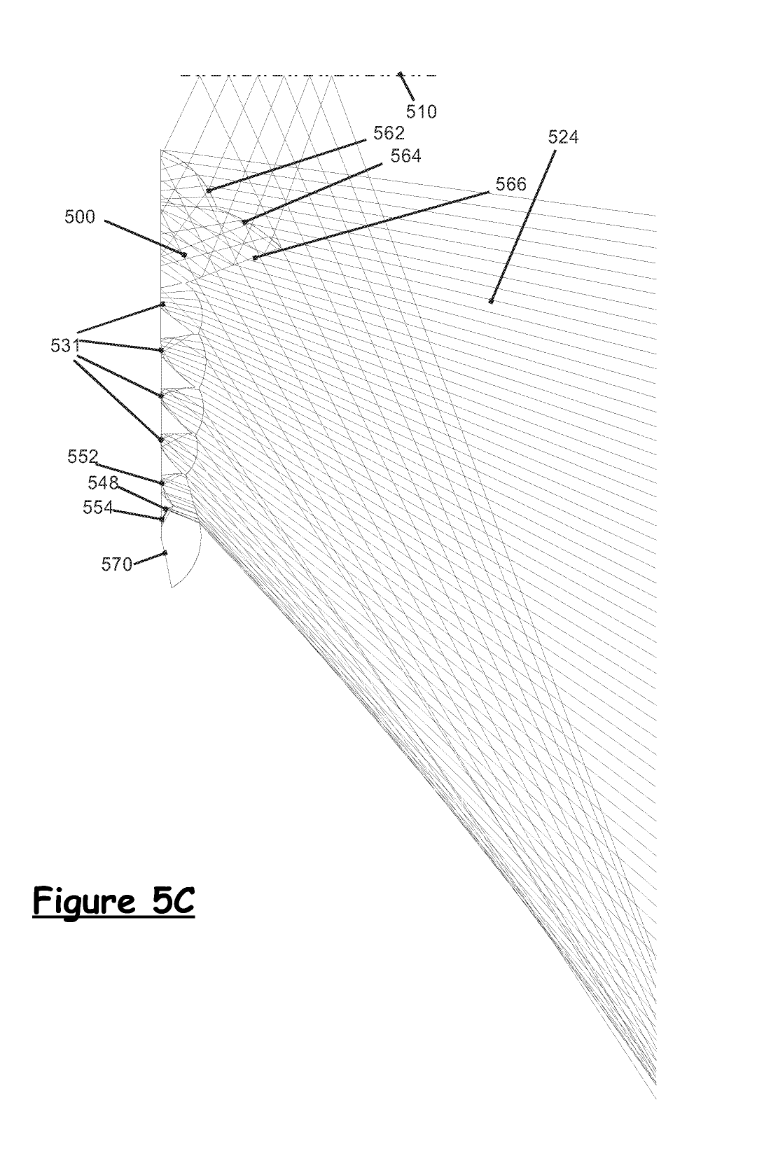

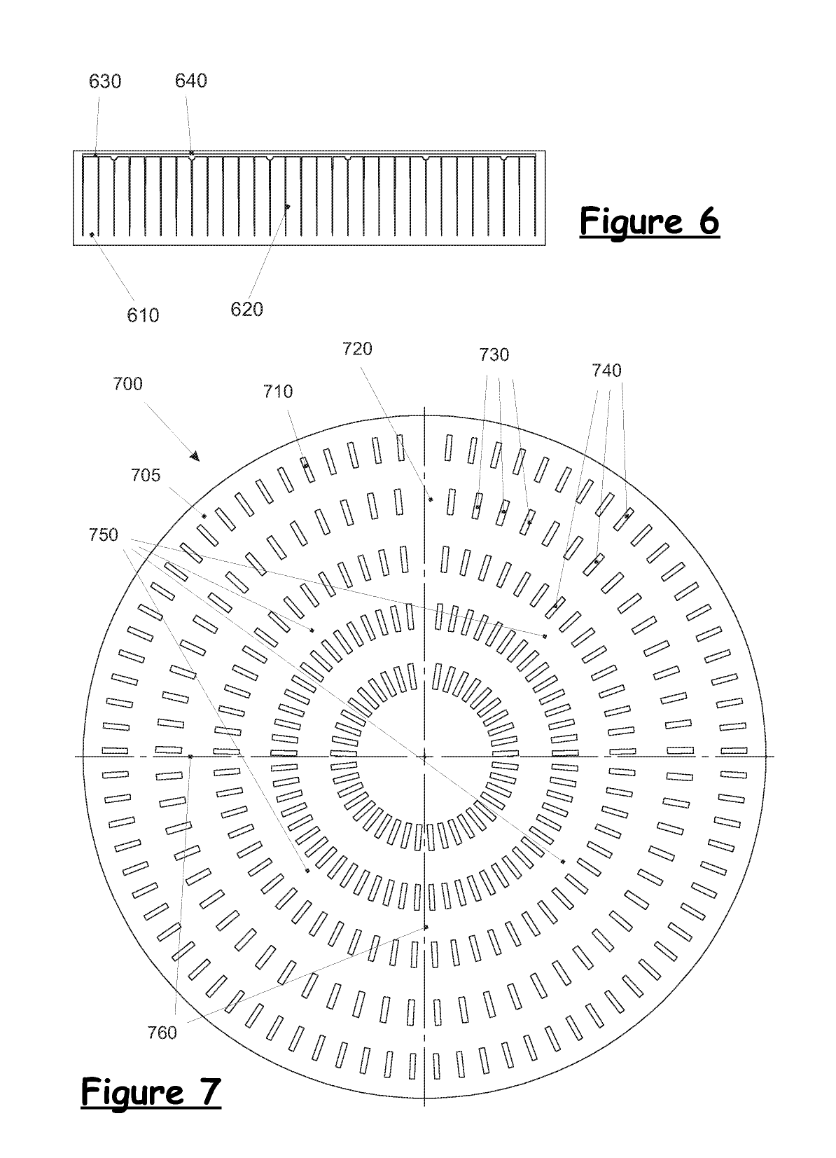

FIG. 7 shows an embodiment of a receiver 700 designed to accommodate a substantially circular lobe comprising an arrangement of die 710 on a low-thermal-resistance circuit board or substrate 705. Other objects, such as bypass diodes, wire bonds, pads, and printed circuit traces are not shown.

In general, a receiver may need to use bypass diodes to handle gross illumination imbalances. Favorable designs limit the need for these diodes, since they add complexity and cost and may generally take up space on the receiver surface. In some embodiments, bypass diodes are employed on a secondary board.

In some embodiments of the present invention, at least one gap in cells 720 is present to reduce the negative impact of shading of support material, e.g., a strut to hold a receiver in front of a reflective primary concentrator. Other embodiments do not employ gaps either because the primary concentrator is unshaded, e.g., for a Fresnel lens primary, shadows are compensated by shaping the primary concentrator, or shadows are compensated by shaping the secondary concentrator, or shadows are compensated by static electrical connections.

In the embodiment shown in FIG. 7, cells are arranged in substantially concentric rings 730 with the long cell direction aligned with the radial direction 740. The embodiment also shows a “hole” in the center 770.

In some embodiments, this hole is produced by the secondary optic system, shadowing of the primary concentrator, shaping of the primary concentrator, or a combination of these techniques. Such a hole is favorable from the standpoint of cell layout and interconnection.

The arrangement of cells in FIG. 7 and the design of cells in FIG. 6 facilitates printed circuit interconnects in the circumferential direction. The relatively large circumferential spacing of cells facilitates radial routing of power traces, particularly in gap regions 720.

The number of cells in the circumferential direction and the radial spacing of the rings can be coordinated with the design of the secondary optical system, to provide a piecewise substantially uniform irradiance on cells. The dashed lines 760 divide the receiver into sectors 750. FIG. 7 shows the receiver divided into four sectors or “quadrants.”

Some embodiments of the present invention divide circumferential strings of cells into sectors that can be paralleled or series connected with other non-adjacent strings of cells to provide compensation. Some designs employ a larger or smaller number of sectors for this compensation. Some designs break rings of cells into different numbers of sectors for each ring to achieve better compensation.

The boundaries of sectors may be staggered circumferentially to improve the compensation.

If cells are series connected, maximum power efficiency occurs when all cells are illuminated to produce the same maximum-efficiency current and the string is operated at maximum-efficiency current. Ensuring that maximum-efficiency current is maintained is the job of a maximum power-point tracker and can be done by a variety of active circuits, outside the scope of the passive electrical compensation.

The maximum power vs. current characteristic of a solar cell has a relatively broad, asymmetric peak. When a string of cells receive finite, but low non-uniform irradiance, the maximum-efficiency current of the string is approximately equal to the average maximum-efficiency current of the individual cells. The broadness of the peak allows modest amounts of non-uniform irradiance to be tolerated with little loss in output power, e.g., a mismatch of 10% of irradiance produces much less than 10% reduction in the power of a string.

Thus individual strings can compensate for small irradiance non-uniformity, provided the total illumination on the string remains substantially constant. Moreover, strings may be series connected with one or more other strings such that the total illumination of the series connected strings is substantially constant with mispointing.

Individual strings should be designed not to have large relative differences in irradiance of the component cells. That is, the total illumination of a string may vary with mispointing, but the cells should nevertheless have substantially balanced maximum-efficiency currents. If such differences are unavoidable, then the cells or series connections of cells having substantially low irradiance should be diode bypassed as known in the art such that the maximum-efficiency current is substantially unaffected by the cells having low-illumination and that the resulting reduction in voltage is minimized.

A string or series connection of strings that experiences a large shift in total illumination with mispointing, may be paralleled with a string or series connection of strings that experiences an opposing shift in total illumination, in such a way that the sum of the maximum-efficiency currents of the paralleled strings or string series is substantially constant with mispointing. These strings or string series should produce substantially the same voltage at their maximum-efficiency currents, and therefore should contain approximately the same number of series connected cells.

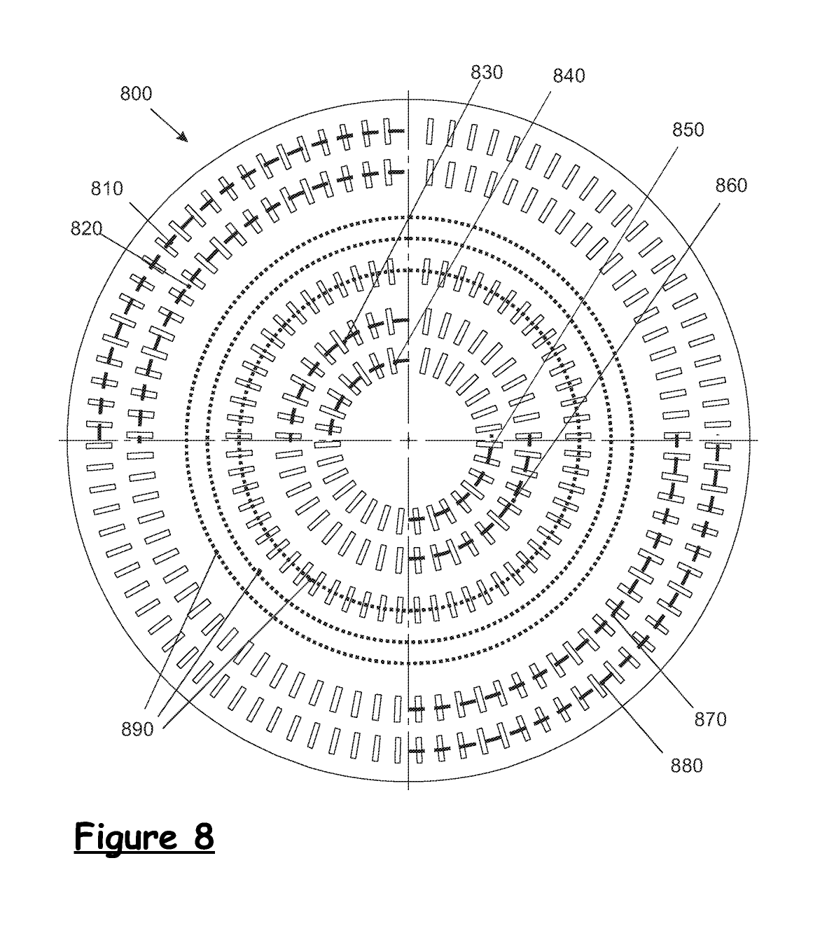

Paralleling strings reduces the output voltage per string, which has the negative effect of requiring more cells to achieve a target module voltage or more conductor material to conduct more current at a lower module voltage. It may be desirable to parallel strings only at the extrema of the illumination pattern produced by the secondary optic. FIG. 8 is an illustration showing a diagram of a receiver 800 having edge-only compensation in quadrants.

In some embodiments, outer rings are paralleled with adjacent inner rings, e.g., 810 is paralleled with 820. In some embodiments, 810 is alternatively paralleled with 880 or 870. In other embodiments, 810 is paralleled with a series combination of 830 and 850, or with a series combination of 840 with 860, or with a series combination of 830 and 840, or with a series combination of 850 and 860. The string 840 may be paralleled with 830 or 850 or 860, depending on the design of the optical compensator.

Cells in the interior of the array 890 may ideally be series connected to maximize the output voltage or may also require parallel combination for compensation.

Strings and series and parallel combinations of strings whose combined total irradiation is “guaranteed by design” to be substantially conserved with mispointing may be paralleled to compensate each other. An example is the case, e.g., that in the outer rings of FIG. 5, where mispointed rays bounce via total internal reflection from one row of cells to another when a threshold mispointing angle is exceeded. In such a case, the total number of photons landing on the paired cells is conserved with tilt, but the relative amounts landing on the cells vary. Paralleling of cells in such locations could be performed at the string level or even the individual cell level.

In some embodiments of the present invention, the secondary optic and receiver are designed so that the maximum-efficiency currents of each compensated combination of strings is substantially identical, so that each compensated string can be series connected. This is favorable since the output of the module is a single pair of wires. However, the process of compensating all sections of the array may require so much paralleling that the module voltage is lower than desired.

Alternatively, a plurality of compensated combinations of strings may provide independent outputs having unmatched currents. These multiple outputs could be combined efficiently through active circuitry that boosts or bucks one or more of the outputs' currents or voltages.

The printed circuit board or substrate on which the die are mounted and series connected has a limited ability to route current from one part of the receiver to another. The vias and multiple-layer printed circuit boards are able to overcome such routing difficulties.

In the case of a high-concentration solar receiver, however, the additional thermal resistance of a multiple dielectric layers may be prohibitively high. Moreover, the cost of specialty, high conductivity dielectrics is substantially higher than that of conventional printed circuit board dielectrics, e.g., FR4 printed circuit board.

Therefore, in accordance with certain embodiments, printed circuit traces leading from strings terminate in off-board connectors in such a way that two or preferably one printed circuitry layer is needed on the receiver. The remainder of interconnects could be done with wire or with a nearby second printed circuit board that does not interfere with heat transfer in the receiver.

This secondary board may also contain bypass diodes, static interconnects, and connectors for distribution. Moreover, this secondary board may further contain active switching hardware including power-point optimization circuitry, sensing, including current and voltage sensing circuitry, tilt-error sensing circuitry, focus sensing circuitry, microcontrollers, capacitors, inductors, and EMI/RFI control circuitry.

A further advantage of putting this circuitry on a secondary board is the ability to change an upgrade the interconnection scheme, e.g., go from one static interconnection network to another one or to go from static interconnection to dynamic (actively switched) interconnection, or to go to active boost/buck circuitry.

If active circuitry is to be used to combine mismatched currents, this circuitry should be designed to operate only to supply or sink difference currents or to boost or buck difference voltages so that the power capacity of the active circuit is reduced and inefficiency in the active circuitry only applies to the power needed to resolve imbalances.

According to an embodiment, an apparatus includes a primary concentrator configured to receive incident light from a light source over a range of acceptance angles, a secondary passive optical compensator configured to receive light from the primary concentrator, and to refract the light and submit the light to at least one total internal reflection, and a receiver further including an array of photovoltaic cells configured to receive from the secondary passive optical compensator, the light which has been subjected to the at least one total internal reflection. The passive optical compensator can include a refracting element distal from the receiver, and a total internal reflectance element proximate to the receiver. The refracting element can be monolithic with the total internal reflectance element.

According to another embodiment, the refracting element can include an external surface proximate to the primary concentrator and configured to refract light received from the primary concentrator. The total internal reflectance element can include a side surface configured to reflect light to an internal surface that is proximate to the receiver.

According to yet another embodiment, the external surface can be curved or straight.

According to yet another embodiment, the side surface can be curved or straight.

According to yet another embodiment, light exiting the internal reflectance element through the internal surface is concentrated and/or more homogenous relative to the incident light.

According to yet another embodiment, the apparatus includes a second side surface configured to direct light back to the curved external surface for reflection to the internal surface. The second side surface can be straight. The second side surface can be disposed proximate to an edge of the secondary passive optical compensator.

According to yet another embodiment, the refracting element is located proximate to a center of the secondary passive optical compensator. The refracting element can include an annulus disposed around the center. The annulus can include a first external surface configured to refract light received from a center portion of the primary concentrator, and a second external surface configured to refract light received at oblique angles from peripheral portions of the concentrator. The first and second surfaces are configured to reflect the refracted light to an internal surface of the total internal reflectance element, the internal surface proximate to the receiver. The first external surface can be curved, and the second external surface can be planar. The internal surface can define recesses channeling light into circumferential bands.

According to yet another embodiment, the apparatus includes a reflective element positioned at a center of the passive secondary optical compensator. The reflective element can be selected from a cone, a cylinder, a tapered cylinder, a prism, a tapered prism, or a paraboloid or hyperboloid or a generalized surface of revolution. The reflective element can have flat faces or concave flutes.

According to yet another embodiment, the apparatus includes a raised reflective ring positioned at an edge of the passive secondary optical compensator and configured to reflect light to the refracting element.

According to yet another embodiment, the apparatus includes a divergent optical compensator positioned above a central region of the secondary passive optical compensator. The divergent optical compensator can include a first refractive surface proximate to the primary concentrator, the first refractive surface configured to redirect light away from the central region. The divergent optical compensator can further include a second refractive surface proximate to the secondary passive optical compensator and configured to internally reflect light refracted by the first surface. The divergent optical compensator can also include a separate tertiary element positioned above the central region utilizing a member.

According to yet another embodiment, the secondary passive optical compensator of the apparatus can include a plurality of refracting elements located distal from the receiver and configured to communicate light to a respective plurality of total internal reflectance elements located proximate to the receiver. The refracting elements can offer different surface areas to light received from the concentrator, and each of the total internal reflectance elements is configured to produce approximately a determined magnitude of irradiance to a corresponding respective photovoltaic cell of the receiver. The total internal reflective elements can be arranged in an array configured to receive light from respective refracting elements, and the photovoltaic cells can be arranged in a second array including strings and corresponding to the array of the total internal reflectance elements. The total internal reflective elements can also be arranged in a radial array and an internal surface of each total internal reflectance element proximate to the receiver has an aspect ratio of (length in a radial direction/length in a circumferential direction) greater than about 1.5, and an aspect ratio of a surface of the photovoltaic cells matches the aspect ratio of the internal surfaces of the total internal reflectance elements. The second array can include a plurality of strings of photovoltaic cells interconnected in series. The strings of the second array in opposing sectors can be connected in parallel and in series to achieve passive electrical compensation. The strings can be connected together on a separate PC board. The apparatus can further include bypass diodes located on a separate PC board. The bypass diodes can be configured to allow the apparatus to produce a plurality of outputs of different voltages or currents.

According to yet another embodiment, the secondary passive optical compensator of the apparatus can include a first glass portion distal from the receiver, and a second polymer portion proximate to the receiver. The first glass portion is bonded to the second polymer portion, is molded to the first glass portion, and/or provides physical support for the second polymer portion. In some embodiments the first glass portion absorbs radiation degrading the second polymer portion. A refracting element configured to receive radiation from the concentrator, can be formed in the first glass portion. A total internal reflecting element configured to receive radiation from the refracting element, can be formed in the second polymer portion. The secondary passive optical compensator can further include a third polymer portion located on a surface of the first glass portion proximate to the receiver. The first glass portion can be planar and the second and third polymer portions can be molded onto the planar first glass portion.

According to an embodiment, an apparatus includes a host computer configured to design a secondary optical compensator configured to be interposed between a solar energy concentrator and a receiver including a plurality of photovoltaic cells. The host computer includes a processor and a computer readable storage medium in electronic communication with the processor. The computer readable medium includes codes configured to instruct the processor to generate an input rayset based upon properties of solar light incident to the concentrator and a tracking error of the concentrator, generate an irradiance distribution profile at the receiver from the input rayset and an optical property of the concentrator, partition the receiver into a plurality of cells, each cell configured to receive a substantially equal portion of the irradiance distribution profile, create a plurality of refractive surfaces of the secondary optic structure, each of the refractive surfaces corresponding to one of the cells of the receiver, create a plurality of second surfaces of the secondary optic structure, each second surface corresponding to one of the refractive surfaces and having a profile configured to communicate light received from the corresponding refractive surface to the corresponding cell of the receiver, and generate a three-dimensional representation of a monolithic secondary optical compensator structure including the plurality of refractive surfaces and the plurality of second surfaces. The code can further be configured to partition the receiver into the plurality of cells based upon input selected from a geometric bound specified by a user, a size of the receiver, a void in the bounds of the receiver, a number of cells, a desired concentration factor, an energy conversion cell dimension, and/or a cell geometry. The code can further be configured to create the plurality of refractive surfaces based upon input selected from an expected amount of concentration, geometric bounds including a starting value and a thickness limit of the secondary optic, a starting value, and a limit on curvature in a particular axis. The code can still further be configured to create the plurality of second surfaces based upon input selected from maximum and minimum angles of taper, and/or a size and shape of an active area of the cell. The computer readable storage medium can further be configured to store code configured to optimize at least one of the following factors based upon a merit function: 1) a curvature of the refractive surface, 2) a profile of the second surface, or 3) a position of the cell relative to the second surface. Optimization of the merit function can be based upon an efficiency of communication of the light to the receiver, or a uniformity of light communicated to the cell.

According to an embodiment, a method includes receiving at a primary concentrator incident light from a light source over a range of acceptance angles, receiving light at a secondary passive optical compensator from the primary concentrator, refracting the received light and subjecting the refracted light to at least one total internal reflection, and receiving at a receiver the light which has been subjected to the at least one total internal reflection. The receiver includes an array of photovoltaic cells.

Having thus described exemplary embodiments of the present invention, it should be noted by those skilled in the art that the within disclosures are exemplary only and that various other alternatives, adaptations, and modifications may be made within the scope of the present invention. Accordingly, the present invention is not limited to the specific embodiments as illustrated herein.

What is claimed is:

1. An apparatus comprising:
a primary concentrator configured to receive incident light from a light source over a range of acceptance angles;
a secondary passive optical compensator configured to receive light from the primary concentrator, and to refract the light and submit the light to at least one total internal reflection; and
a receiver comprising an array of photovoltaic cells configured to receive from the secondary passive optical compensator, the light which has been subjected to the at least one total internal reflection.

2. The apparatus of claim 1 wherein the passive optical compensator comprises a refracting element distal from the receiver, and a total internal reflectance element proximate to the receiver.

3. The apparatus of claim 2 wherein the refracting element is monolithic with the total internal reflectance element.

4. The apparatus of claim 2 wherein:
the refracting element comprises an external surface proximate to the primary concentrator and configured to refract light received from the primary concentrator; and
the total internal reflectance element comprises a side surface configured to reflect light to an internal surface that is proximate to the receiver.

5. The apparatus of claim 4 wherein the external surface is curved or straight.

6. The apparatus of claim 4 wherein the side surface is curved or straight.

7. The apparatus of claim 4 wherein light exiting the internal reflectance element through the internal surface is concentrated and/or more homogenous relative to the incident light.

8. The apparatus of claim 4 further comprising:
a second side surface configured to direct light back to the curved external surface for reflection to the internal surface.

9. The apparatus of claim 8 wherein the second side surface is disposed proximate to an edge of the secondary passive optical compensator.

10. The apparatus of claim 2 wherein the refracting element is located proximate to a center of the secondary passive optical compensator.

11. The apparatus of claim 10 wherein the refracting element comprises an annulus disposed around the center, the annulus comprising:
a first external surface configured to refract light received from a center portion of the primary concentrator; and
a second external surface configured to refract light received at oblique angles from peripheral portions of the concentrator, wherein,
the first and second surfaces are configured to reflect the refracted light to an internal surface of the total internal reflectance element, the internal surface proximate to the receiver.

12. The apparatus of claim 2 further comprising a reflective element positioned at a center of the passive secondary optical compensator.

13. The apparatus of claim 2 further comprising a raised reflective ring positioned at an edge of the passive secondary optical compensator and configured to reflect light to the refracting element.

14. The apparatus of claim 2 further comprising a divergent optical compensator positioned above a central region of the secondary passive optical compensator.

15. The apparatus of claim 1 wherein the secondary passive optical compensator comprises a plurality of refracting elements located distal from the receiver and configured to communicate light to a respective plurality of total internal reflectance elements located proximate to the receiver.

16. The apparatus of claim 15 wherein:
the refracting elements offer different surface areas to light received from the concentrator; and
each of the total internal reflectance elements is configured to produce approximately a determined magnitude of irradiance to a corresponding respective photovoltaic cell of the receiver.

17. The apparatus of claim 16 wherein:
the total internal reflective elements are arranged in an array configured to receive light from respective refracting elements; and
the photovoltaic cells are arranged in a second array comprising strings and corresponding to the array of the total internal reflectance elements.

18. The apparatus of claim 17 wherein:
the total internal reflective elements are arranged in a radial array and an internal surface of each total internal reflectance element proximate to the receiver has an aspect ratio of (length in a radial direction/length in a circumferential direction) greater than about 1.5; and
an aspect ratio of a surface of the photovoltaic cells matches the aspect ratio of the internal surfaces of the total internal reflectance elements.

19. The apparatus of claim 1 wherein the secondary passive optical compensator comprises a first glass portion distal from the receiver, and a second polymer portion proximate to the receiver.

20. An apparatus comprising a host computer configured to design a secondary optical compensator configured to be interposed between a solar energy concentrator and a receiver comprising a plurality of photovoltaic cells, the host computer comprising:
a processor; and
a computer readable storage medium in electronic communication with the processor and having stored thereon codes configured to instruct the processor to,
generate an input rayset based upon properties of solar light incident to the concentrator and a tracking error of the concentrator,
generate an irradiance distribution profile at the receiver from the input rayset and an optical property of the concentrator,
partition the receiver into a plurality of cells, each cell configured to receive a substantially equal portion of the irradiance distribution profile,
create a plurality of refractive surfaces of the secondary optic structure, each of the refractive surfaces corresponding to one of the cells of the receiver;
create a plurality of second surfaces of the secondary optic structure, each second surface corresponding to one of the refractive surfaces and having a profile configured to communicate light received from the corresponding refractive surface to the corresponding cell of the receiver, and
generate a three-dimensional representation of a monolithic secondary optical compensator structure comprising the plurality of refractive surfaces and the plurality of second surfaces.

21. The apparatus of claim 20 wherein the code of the computer-readable storage medium is configured to partition the receiver into the plurality of cells based upon input selected from a geometric bound specified by a user, a size of the receiver, a void in the bounds of the receiver, a number of cells, a desired concentration factor, an energy conversion cell dimension, and/or a cell geometry.

22. The apparatus of claim 20 wherein the code of the computer-readable storage medium is configured to create the plurality of refractive surfaces based upon input selected from an expected amount of concentration, geometric bounds including a starting value and a thickness limit of the secondary optic, a starting value, and a limit on curvature in a particular axis.

23. The apparatus of claim 20 wherein the code of the computer-readable storage medium is configured to create the plurality of second surfaces based upon input selected from maximum and minimum angles of taper, and/or a size and shape of an active area of the cell.

24. The apparatus of claim 20 wherein the computer-readable storage medium has further stored thereon code configured to optimize at least one of the following factors based upon a merit function: a curvature of the refractive surface, a profile of the second surface, or a position of the cell relative to the second surface.

25. A method comprising:
receiving at a primary concentrator incident light from a light source over a range of acceptance angles;
receiving light at a secondary passive optical compensator from the primary concentrator, refracting the received light and subjecting the refracted light to at least one total internal reflection; and
receiving at a receiver the light which has been subjected to the at least one total internal reflection,
wherein the receiver comprises an array of photovoltaic cells.
